(19) United States
(12) Patent Application Publication
(10) Pub. No.: US 2026/0162691 A1
(43) Pub. Date: Jun. 11, 2026

(54) SEMICONDUCTOR DEVICE INCLUDING MEMORY CELL ARRAY

(71) Applicant: Taiwan Semiconductor Manufacturing Company, Ltd., Hsinchu (TW)

(72) Inventors: Chao Yuan CHENG, Hsinchu (TW); Yao-Jen YANG, Hsinchu (TW); Chia-En HUANG, Hsinchu (TW); Ting-Wei CHIANG, Hsinchu (TW)

(73) Assignee: Taiwan Semiconductor Manufacturing Company, Ltd., Hsinchu (TW)

(21) Appl. No.: 19/079,806

(22) Filed: Mar. 14, 2025

Related U.S. Application Data
(60) Provisional application No. 63/729,140, filed on Dec. 6, 2024.

(51) Int. Cl. G11C 5/06; H01L 23/522; H01L 23/528

(52) U.S. Cl. CPC G11C 5/063; H10W 20/42; H10W 20/43; H10W 20/435

(57) ABSTRACT

An embodiment semiconductor device includes a memory cell array, a first conductive structure configured to carry a first control signal for an operation of a set of memory cells of the memory cell array, and a second conductive structure electrically coupled to the first conductive structure and configured to carry the first control signal for the operation of the set of memory cells of the memory cell array. Memory cells of the set of memory cells are arranged along a first horizontal direction. The first conductive structure and the second conductive structure extend along the first horizontal direction. The first conductive structure and the second conductive structure are spaced apart in a second horizontal direction, in a vertical direction, or both.

### PRIORITY CLAIM AND CROSS-REFERENCE

This patent application claims the benefit of U.S. Provisional Patent Application No.: 63/729,140 filed on Dec. 6, 2024, the entire disclosure of which is hereby incorporated by reference.

### BACKGROUND

Modern integrated circuit (IC) manufacturing technology enables faster, smaller, and more efficient devices. In many applications, the size of electrical components and transistors has shrunk to include more components in a semiconductor die, or even more layers of components in a semiconductor die. These advances in IC manufacturing technology have supported the development of a wide variety of digital devices, such as a semiconductor device including a memory cell array for storing data.

In some applications, a semiconductor device including a memory cell array further includes conductive structures configured to carry control signals for the operations of the memory cell array, such as a read operation, a write operation, an erase operation, a combination thereof, or the like. With the size of the electrical components and transistors becoming smaller, the area for implementing the conductive structures for carrying the control signals also becomes smaller. In some applications, the resistance level of a conductive structure increases as its line width decreases. In some applications, the driving load of a signal line and the corresponding signal delay increase with the resistance level of the signal line.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic block diagram of a memory device, in accordance with some embodiments.

FIG. 2 is a cross-sectional view of a semiconductor device, in accordance with some embodiments.

FIGS. 3A-3B are layout diagrams of a first layout example, in accordance with some embodiments.

FIGS. 3C-3D are cross-sectional views of a semiconductor device based on the first layout example in FIGS. 3A-3B, in accordance with some embodiments.

FIG. 4A is a layout diagram of a second layout example, in accordance with some embodiments.

FIGS. 4B-4C are cross-sectional views of a semiconductor device based on the second layout example in FIG. 4A, in accordance with some embodiments.

FIG. 5A is a layout diagram of a third layout example, in accordance with some embodiments.

FIGS. 5B-5C are cross-sectional views of a semiconductor device based on the third layout example in FIG. 5A, in accordance with some embodiments.

FIG. 6A is a layout diagram of a fourth layout example, in accordance with some embodiments.

FIGS. 6B-6C are cross-sectional views of a semiconductor device based on the fourth layout example in FIG. 6A, in accordance with some embodiments.

FIG. 7A is a layout diagram of a fifth layout example, in accordance with some embodiments.

FIGS. 7B-7C are cross-sectional views of a semiconductor device based on the fifth layout example in FIG. 7A, in accordance with some embodiments.

FIG. 8A is a layout diagram of a sixth layout example, in accordance with some embodiments.

FIGS. 8B-8C are cross-sectional views of a semiconductor device based on the sixth layout example in FIG. 8A, in accordance with some embodiments.

FIGS. 9A-9C are plan views of floor plan examples of a semiconductor device that includes a memory device, in accordance with some embodiments.

FIGS. 10A-10B are cross-sectional views of semiconductor device examples, in accordance with some embodiments.

FIG. 11 is a flowchart of a method of manufacturing a semiconductor device, in accordance with some embodiments.

FIG. 12 is a block diagram of an electronic design automation (EDA) system in accordance with some embodiments.

FIG. 13 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

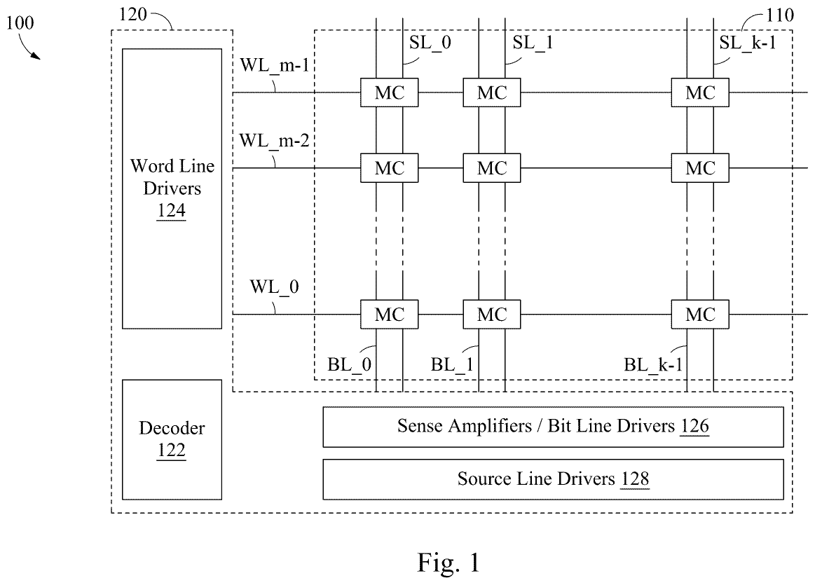

FIG. 1 is a schematic block diagram of a memory device 100, in accordance with some embodiments. In some embodiments, memory device 100 is included in a semiconductor device. In some embodiments, the semiconductor device that includes memory device 100 further includes other components and/or circuitry for other functionalities.

In FIG. 1, memory device 100 includes a memory cell array 110 and control circuitry 120 coupled to memory cell array 110. Memory cell array 110 includes memory cells (labeled as “MC” in FIG. 1) arranged in rows and columns. In some embodiments, control circuitry 120 is configured to control operations of memory cells of memory cell array 110. In FIG. 1, as a non-limiting example, memory device 100 further includes a plurality of word lines WL_0 to WL_m-1 extending along a row direction, a plurality of bit lines (also referred to as “data lines”) BL_0 to BL_k-1 extending along a column direction, and a plurality of source lines SL_0 to SL_k-1 extending along the column direction of memory cell array 110. Each of the memory cells MC is coupled to control circuitry 120 by at least one of the word lines, at least one of the bit lines, and at least one of the source lines.

Examples of word lines include, but are not limited to, read word lines for carrying read word line signals based on the addresses of the memory cells MC to be read from, write word lines for carrying write word line signals based on the addresses of the memory cells MC to be written to, or the like. In at least one embodiment, a set of word lines is configured to function as both read word lines and write word lines. Examples of bit lines include read bit lines for carrying data signals read from the memory cells MC activated by corresponding word lines, write bit lines for carrying data signals to be written to the memory cells MC activated by corresponding word lines, or the like. In at least one embodiment, a set of bit lines is configured to function as both read bit lines and write bit lines. In one or more embodiments, each memory cell MC is coupled to a pair of bit lines referred to as a bit line and a bit line bar (or a complementary bit line). In some embodiments, the source lines are configured to carry source line signals that correspond to establishing current paths of selected subsets of memory cells MC based on the addresses of the memory cells MC.

The word lines are also referred to in this disclosure as WL, the bit lines are also referred to in this disclosure as BL, and the source lines are also referred to in this disclosure as SL. Various numbers of word lines, bit lines, and/or source lines in memory device 100 are within the scope of various embodiments. In FIG. 1 as a non-limiting example, the source lines extend along the column direction. In some other embodiments, the source lines extend along the row direction. In some other embodiments, the source lines are omitted.

In FIG. 1 as a non-limiting example, control circuitry 120 includes a decoder 122, a plurality of word line drivers 124, a plurality of sense amplifiers and/or bit line drivers 126, and a plurality of source line drivers 128. In some embodiments, decoder 122 interprets at least a portion of an address to be accessed during a read operation or a write operation, and activates a corresponding one of word line drivers 124 to active one of the word lines that corresponds to the address. In some embodiments, the selected one of the word line drivers 124 activates a specific row based on activating the corresponding word line to enable access to the memory cells in the row. In some embodiments, decoder 122 interprets at least another portion of the address and selects one of sense amplifiers and/or bit line drivers 126 coupled to one of the bit lines that corresponds to the address. In some embodiments, the selected one of sense amplifiers and/or bit line drivers 126 is configured to read the binary value stored in the memory cell specified by the decoded row and column via the corresponding bit line. In some embodiments, the selected one of sense amplifiers and/or bit line drivers 126 is configured to write the binary value to be stored in the memory cell specified by the decoded row and column via the corresponding bit line. In some embodiments, decoder 122 further selectively activate one of the source line drivers 128 in order to supply a voltage to a selected source line and a different voltage to unselected source lines. In some embodiments, the source lines and the source line drivers 128 are omitted.

In some embodiments, control circuitry 120 further includes one or more clock generators for providing clock signals for various components of the memory device 100, one or more input/output (I/O) circuits for data exchange with external devices, and/or one or more control circuit blocks for controlling various operations in the memory device 100. In some embodiments, the configuration of memory device 100 is usable and/or modifiable to implement a read-only memory device, a write-once memory device, an erasable memory device, a reprogrammable memory device, or a read-write memory device. In some embodiments, the memory cells MC correspond to volatile memory cells, such as dynamic random access memory (DRAM) cells or static random access memory (SRAM) cells. In some embodiments, the memory cells MC correspond to non-volatile memory cells, such as floating-gate memory cells, ferroelectric random access memory (FRAM) cells, magnetic random access memory (MRAM) cells, phase-change memory (PCM) cells, or resistive random access memory (RRAM) cells.

In FIG. 1, memory device 100 includes one memory cell array 110 as a non-limiting example. In some embodiments, a memory device includes one or more memory cell arrays controllable by one control circuitry.

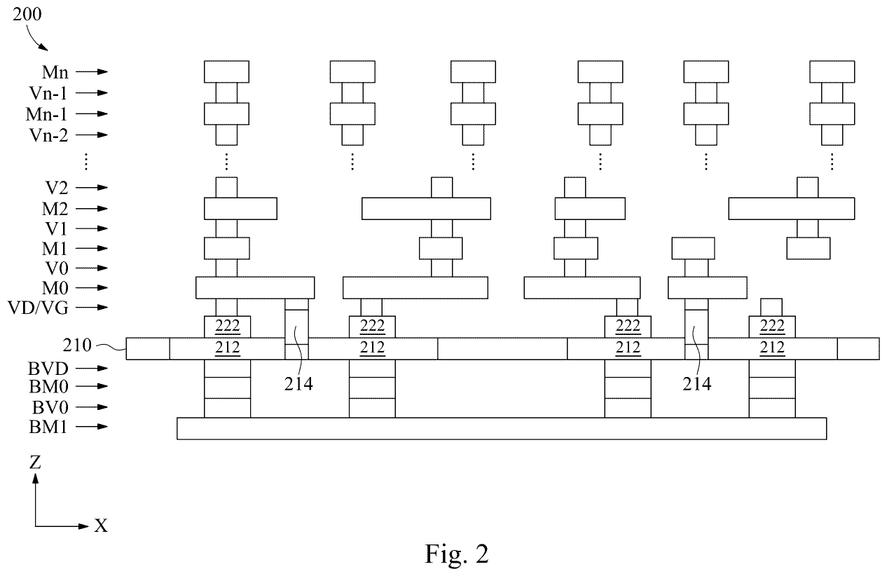

FIG. 2 is a cross-sectional view of a semiconductor device 200, in accordance with some embodiments. In some embodiments, semiconductor device 200 includes a memory device configured based on the example in FIG. 1. In some embodiments, the cross-sectional view is a simplified cross-sectional view, with many features simplified or not depicted.

Semiconductor device 200 in FIG. 2 includes a substrate 210 with active regions 212 and gate structures 214 formed on or partially in substrate 210. In this example, semiconductor device 200 includes metal-to-drain/source (MD) structures 222 coupled to the active regions 212. In this example, semiconductor device 200 includes via-to-drain/source (VD) structures coupled to MD structures 222 and via-to-gate (VG) structures coupled to gate structures 214 at a VD/VG layer above substrate 210 (with respect to a direction Z). In some embodiments, semiconductor device 200 further includes a plurality of metallization layers (e.g., M0, M1, M2, . . . , Mn-1, and Mn layers) and a plurality of via layers (e.g., V0, V1, V2, . . . , Vn-2, and Vn-1 layers) over the VD/VG layer and substrate 210 (n being a positive integer). In some embodiments, a number of metallization layers over substrate 210 ranges from 8 to 14. In some embodiments, Vn-1 layer denotes the via structures between and connecting conductive lines in Mn-1 layer and Mn layer. In some embodiments, M0 layer denotes the first metallization layer above substrate 210. In some embodiments, the plurality of metallization layers and the plurality of via layers include a conductive material including copper, aluminum, gold, tungsten, a combination thereof, or the like.

Semiconductor device 200 in FIG. 2, as a non-limiting example, further includes conductive structures disposed under substrate 210. For example, semiconductor device 200 further includes backside metallization layers BM0 and BM1 and backside via layers BVD and BV0. In this example, BVD layer denotes backside via structures between and connecting active regions 212 and backside conductive lines in BM0 layer; and BV0 layer denotes backside via structures between and connecting backside conductive lines in BM0 layer and BM1 layer. In some embodiments, BM0 layer denotes the first metallization layer under substrate 210. In this example, semiconductor device 200 includes two backside metallization layers and corresponding via layers. In some embodiments, a number of backside metallization layers under substrate 210 ranges from 2 to 6. In some embodiments, a portion or all of the backside conductive structures (e.g., backside metallization layers BM0 and BM1 and backside via layers BVD and BV0) are at least partially embedded in substrate 210. In some embodiments, backside metallization layers BM0 and BM1 and backside via layers BVD and BV0 include a conductive material including copper, aluminum, gold, tungsten, a combination thereof, or the like. In some other embodiments, a semiconductor device does not include any backside conductive structures.

In some embodiments, semiconductor device 200 includes one or more redistribution layers and conductive pad structures (not in FIG. 2) over the one or more redistribution layers. In some embodiments, semiconductor device 200 further includes conductive terminal structures (e.g., conductive bumps, copper pillar bumps, solder bumps, or the like, not in FIG. 2) over the conductive pad structures. In some embodiments, semiconductor device 200 also includes one or more backside redistribution layers and backside conductive pad structures (not in FIG. 2) under the one or more backside redistribution layers. In some embodiments, semiconductor device 200 also includes backside conductive terminal structures (e.g., conductive bumps, copper pillar bumps, solder bumps, or the like, not in FIG. 2) under the backside conductive pad structures.

In some embodiments, semiconductor device 200 includes transistors formed based on active regions 212 and gate structures 214 in a front-end-of-line (FEOL) portion of semiconductor device 200. In some embodiments, memory cells of a memory device (e.g., memory cells MC of memory device 100 in FIG. 1) are formed based on electrically connecting the transistors in the FEOL portion of semiconductor device 200. In some embodiments, a portion of semiconductor device 200 at and above a given metallization layer (e.g., a M5layer and above) correspond to a back-end-of-line (BEOL) portion of semiconductor device 200. In some embodiments, memory cells of a memory device (e.g., memory cells MC of memory device 100 in FIG. 1) are formed based on electrically connecting transistors, capacitors, and/or resistors formed in the BEOL portion of semiconductor device 200. Moreover, in some embodiments, the control circuitry of a memory device (e.g., control circuitry 120 of memory device 100 in FIG. 1) is formed based on electrically connecting the transistors in the FEOL portion of semiconductor device 200.

According to one or more examples of this disclosure, in order to reduce the resistance of a signal line of a memory device (e.g., a bit line, a word line, or a source line), the signal line is implemented based on a plurality of parallel, electrically coupled conductive structures. In some embodiments, the plurality of conductive structures corresponding to the same signal line are spaced apart in a horizonal direction, in a vertical direction, or a combination thereof. In some embodiments, the plurality of conductive structures reduces the effective resistance of the corresponding signal line. In some embodiments, a portion of the plurality of conductive structures has an enlarged line width, which further reduces the effective resistance of the corresponding signal line.

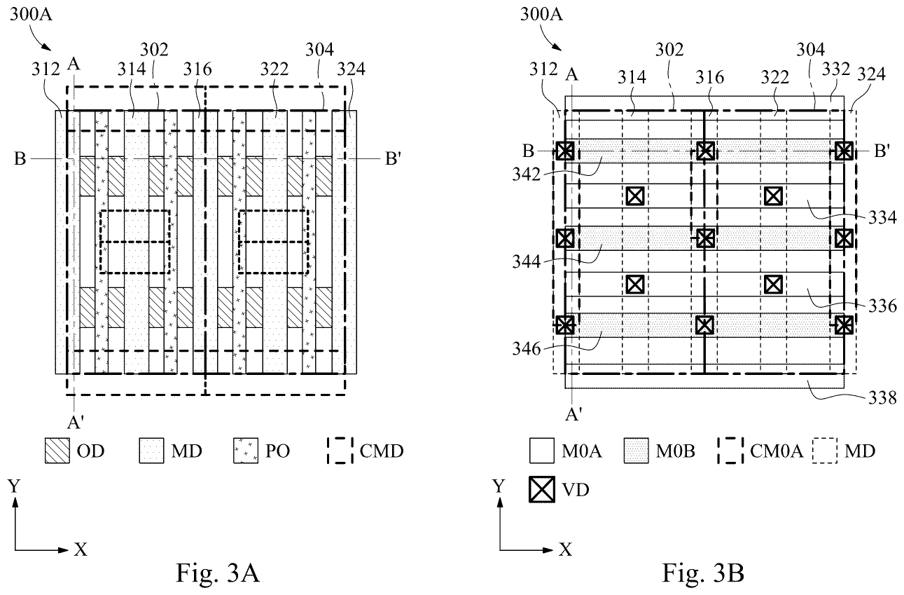

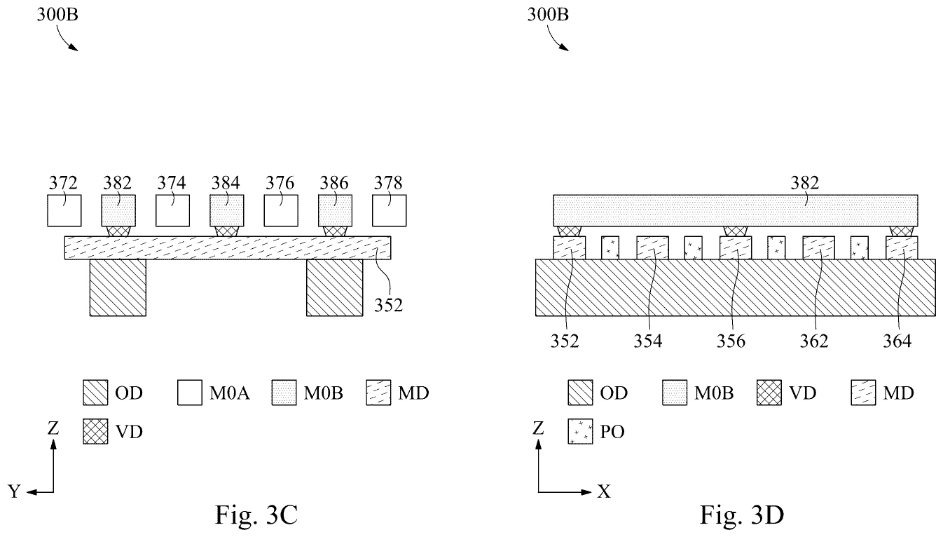

FIG. 3A is a layout diagram of a first portion of a first layout example 300A, in accordance with some embodiments. FIG. 3B is a layout diagram of a second portion of first layout example 300A indicating layout patterns over the first portion in FIG. 3A, in accordance with some embodiments. FIGS. 3A-3B correspond to a portion of first layout example 300A as a non-limiting example. In this example, first layout example 300A is for forming a memory device. In FIGS. 3A-3B, first layout example 300A corresponds to two two-unit cells 302 and 304. In FIGS. 3A-3B as a non-limiting example, each one of two-unit cells 302 and 304 corresponds to two memory cells (e.g., two-unit cells 302 and 304 being configured as four memory cells).

FIG. 3A includes legends of various types of layout patterns used in FIG. 3A. In FIG. 3A, the layout patterns of first layout example 300A include oxide diffusion (OD) patterns (corresponding to “OD” in the legend) indicating active regions of transistors. In some embodiments, the active regions include doped semiconductor materials suitable for forming drain/source structures of transistors and define regions suitable for forming channel structures of transistors. In this non-limiting example, the OD patterns extend along a first direction (e.g., the X direction). In FIG. 3A, the layout patterns of first layout example 300A include polysilicon gate patterns (corresponding to “PO” in the legend) indicative of polysilicon gate structures. In some embodiments, the polysilicon gate structures are used as functional gate structures, dummy gate structures, or placeholder structures on which functional structures and dummy structures are formed. In FIG. 3A, the layout patterns of first layout example 300A further include metal-to-drain/source (MD) patterns 312, 314, 316, 322, and 324 (corresponding to “MD” in the legend) and cut MD patterns (corresponding to “CMD” in the legend) together indicative of MD structures. In this non-limiting example, the PO patterns and the MD patterns extend along a second direction (e.g., the Y direction). In some embodiments, the transistors in two-unit cells 302 and 304 are configured as four memory cells.

In addition, FIG. 3B includes legends of various types of layout patterns used in FIG. 3B. In FIG. 3B, MD patterns 312, 314, 316, 322, and 324 (corresponding to “MD” in the legend) are the same as the MD patterns in FIG. 3A but with different shades in the drawings for clarity. In FIG. 3B, first layout example 300A includes a first set of M0 patterns 332, 334, 336, and 338 (corresponding to “M0A” in the legend) and cut M0A patterns (corresponding to “CM0A” in the legend) together indicative of a first set of conductive structures in the M0 metallization layer. In FIG. 3B, first layout example 300A includes a second set of M0 patterns 342, 344, and 346 (corresponding to “M0B” in the legend) indicative of a second set of conductive structures in the M0 metallization layer. Moreover, in FIG. 3B, first layout example 300A includes VD patterns (corresponding to “VD” in the legend) indicative of VD structures. In this non-limiting example, first layout example 300A includes five M0 patterns 334, 336, 342, 344, and 346 within the cell boundaries and two M0 patterns 332 and 338 overlapping the upper and lower cell boundaries of two-unit cell 302 and/or two-unit cell 304. In this example, two-unit cell 302 and two-unit cell 304 have a cell height along the second direction (e.g., the Y direction) that is greater than six track pitches and less than seven track pitches of the M0 layer.

In FIG. 3B, M0 pattern 334 is indicative of a conductive structure corresponding to a first bit line electrically coupled to the memory cells represented by the upper portions of two-unit cell 302 and two-unit cell 304. Also, M0 pattern 336 is indicative of a conductive structure corresponding to a second bit line electrically coupled to the memory cells represented by the lower portions of two-unit cell 302 and two-unit cell 304. In this example, the first bit line indicated by M0 pattern 334 is electrically coupled to the metal-to-drain/source structures indicated by MD patterns 314 and 322 through via structures indicated by corresponding VD patterns. Also, the second bit line indicated by M0 pattern 336 is electrically coupled to the metal-to-drain/source indicated by MD patterns 314 and 322 through via structures indicated by corresponding VD patterns.

In FIG. 3B, M0 patterns 342, 344, and 346 are indicative of conductive structures corresponding to a source line electrically coupled to the memory cells represented by two-unit cell 302 and two-unit cell 304. In this example, the source line indicated by M0 patterns 342, 344, and 346 is electrically coupled to the metal-to-drain/source indicated by MD patterns 312, 316, and 324 through the via structures indicated by corresponding VD patterns. In FIG. 3B, the conductive structures indicated by M0 patterns 342, 344, and 346 are included in a same metallization layer (e.g., M0 layer) and are spaced apart in a second direction (e.g., the Y direction). In some embodiments, the adjacent ones of M0 patterns 342, 344, and 346 are spaced apart by a distance that is greater than a minimal pitch of VD patterns in order to accommodate multiple via structures between the source line (e.g., indicated by M0 patterns 342, 344, and 346) and the corresponding metal-to-drain/source structures (e.g., indicated by MD patterns 312, 316 and 324).

FIGS. 3C-3D are cross-sectional views of a semiconductor device 300B that includes the memory device based on first layout example 300A in FIGS. 3A-3B, in accordance with some embodiments. FIG. 3C corresponds to a cross-sectional view taken along a first reference line A-A′ in FIGS. 3A-3B. FIG. 3D corresponds to a cross-sectional view taken along a second reference line B-B′ in FIGS. 3A-3B. In FIGS. 3C-3D, various structures are represented using the same legend as the corresponding layout patterns in FIGS. 3A-3B, and the description thereof is simplified or omitted. Also, FIGS. 3C-3D are simplified cross-sectional views, and various features of semiconductor device 300B are simplified or omitted in FIGS. 3C-3D.

In FIG. 3C, semiconductor device 300B includes an OD structure (corresponding to “OD” in the legend) over a substrate (e.g., substrate 210 in FIG. 2) of semiconductor device 300B, a metal-to-drain/source structure 352 (corresponding to “MD” in the legend and as indicated by MD pattern 312) over the OD structure, and M0 conductive structures 372, 374, 376, and 378 (corresponding to “M0A” in the legend and as indicated by M0A patterns 332, 334, 336, and 338) and M0 conductive structures 382, 384, and 386 (corresponding to “M0B” in the legend and as indicated by M0B patterns 342, 344, and 346) over metal-to-drain/source structure 356. In FIG. 3C, M0 conductive structures 382, 384, and 386 correspond to a source line and are electrically coupled to metal-to-drain/source structure 356 through three via structures (corresponding to “VD” in the legend).

In FIG. 3D, semiconductor device 300B includes an OD structure (corresponding to “OD” in the legend) over the substrate (e.g., substrate 210 in FIG. 2) of semiconductor device 300B, metal-to-drain/source structures 352, 354, 356, 362, and 364 (corresponding to “MD” in the legend and as indicated by MD patterns 312, 314, 316, 322, and 324) over the OD structure, and M0 conductive structure 382 (corresponding to “M0B” in the legend and as indicated by M0B pattern 342) over metal-to-drain/source structures 352, 354, 356, 362, and 364. In FIG. 3D, M0 conductive structure 382 corresponds to (a part of) a source line and is electrically coupled to metal-to-drain/source structures 352, 356, and 364 through three via structures (corresponding to “VD” in the legend).

In view of the examples in FIGS. 3A-3D, in some embodiments, a semiconductor device (e.g., semiconductor device 300B) includes a memory cell array, a first conductive structure (e.g., M0 conductive structure 382) configured to carry a first control signal (e.g., a source line signal) for an operation of a set of memory cells of the memory cell array, and a second conductive structure (e.g., M0 conductive structure 384 and/or M0 conductive structure 386) electrically coupled to the first conductive structure and configured to carry the first control signal for the operation of the set of memory cells. In some embodiments, memory cells of the set of memory cells are arranged along a first horizontal direction (e.g., the X direction), and the first conductive structure and the second conductive structure extend along the first horizontal direction.

In view of the examples in FIGS. 3A-3D, in some embodiments, the first conductive structure and the second conductive structure are spaced apart in a second horizontal direction (e.g., the Y direction). In some embodiments, the first conductive structure and the second conductive structure are included in a same metallization layer (e.g., M0 layer). In some embodiments, the semiconductor device (e.g., semiconductor device 300B) further includes a third conductive structure (e.g., metal-to-drain/source structure 356) extending along the second horizontal direction. In some embodiments, the semiconductor device includes a plurality of via structures connecting the third conductive structure and the first conductive structure and the second conductive structure. In some embodiments, the additional conductive structures and via structures further reduce the resistance of the corresponding signal line (e.g., a source line in this example).

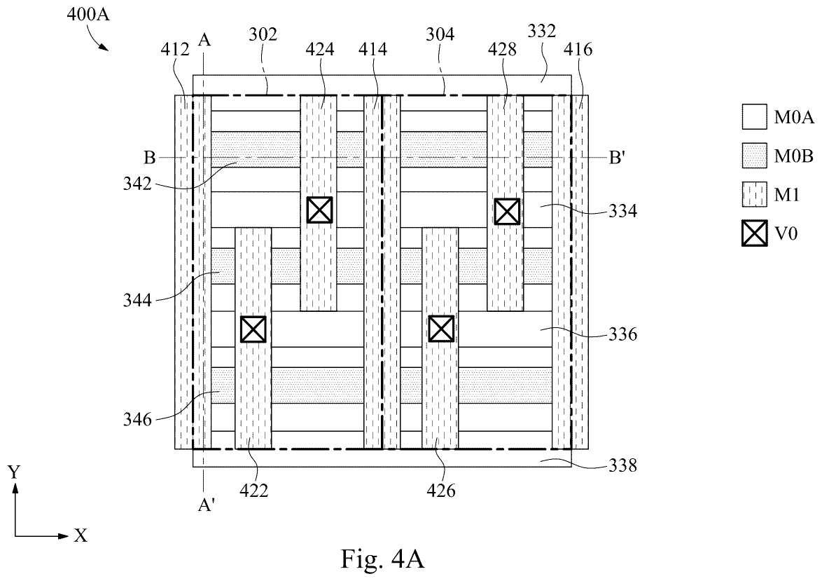

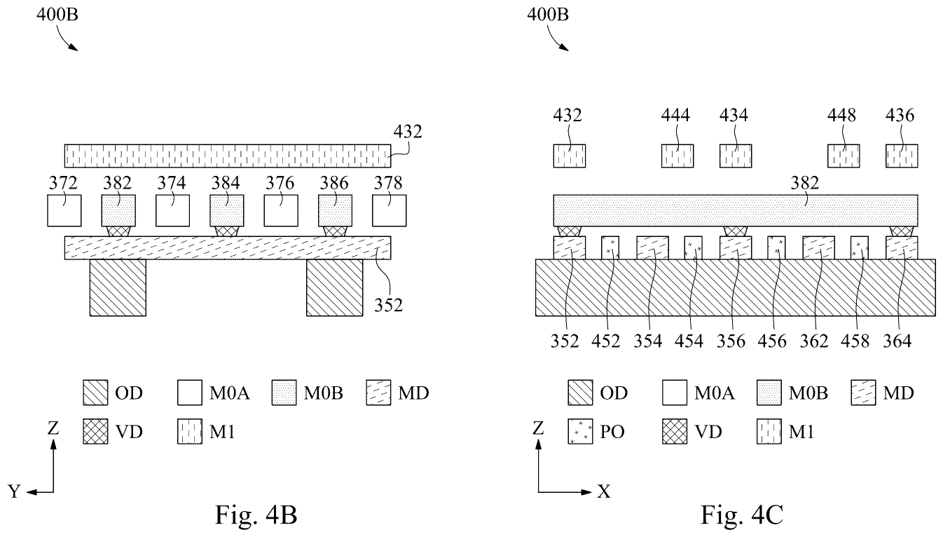

FIG. 4A is a layout diagram of a portion of a second layout example 400A, in accordance with some embodiments. In some embodiments, second layout example 400A is based on, or a variation of, first layout example 300A, and incorporates the portions in FIGS. 3A-3B. In FIG. 4A, various layout patterns that are the same or similar to those in FIGS. 3A-3B are represented using the same legend and given the same reference numbers, and the description thereof is simplified or omitted.

Compared to the layout diagrams in FIGS. 3A-3B, second layout example 400A in FIG. 4A further includes M1 patterns 412, 414, 416, 422, 424, 426, and 428 (corresponding to “M1” in the legend) indicative of conductive structures in the M1 layer. In FIG. 4A, second layout example 400A further include V0 patterns (corresponding to “V0” in the legend) indicative of V0 structures. In FIG. 4A, M1 pattern 412 is indicative of a conductive structure corresponding to a first word line electrically coupled to the memory cells represented by the two-unit cell 302; and M1 pattern 414 is indicative of a conductive structure corresponding to a second word line electrically coupled to the memory cells represented by the two-unit cell 304. In FIG. 4A, M1 patterns 422, 424, 426, and 428 are indicative of conductive structures corresponding to various bit lines electrically coupled to different M0 conductive structures thereunder through the via structures indicated by the V0 patterns.

FIGS. 4B-4C are cross-sectional views of a semiconductor device 400B that includes the memory device based on second layout example 400A in FIG. 4A, which is further based on first layout example 300A in FIGS. 3A-3B, in accordance with some embodiments. FIG. 4B corresponds to a cross-sectional view taken along the first reference line A-A′ in FIGS. 3A-3B and 4A. FIG. 4C corresponds to a cross-sectional view taken along the second reference line B-B′ in FIGS. 3A-3B and 4A. In FIGS. 4B-4C, various structures are represented using the same legend as the corresponding layout patterns in FIGS. 3A-3B and 4A, and the description thereof is simplified or omitted. Also, FIGS. 4B-4C are simplified cross-sectional views, and various features of semiconductor device 400B are simplified or omitted in FIGS. 4B-4C.

In FIG. 4B, compared to semiconductor device 300B in FIG. 3C, semiconductor device 400B further includes a conductive structure 432 (corresponding to “M1” in the legend and as indicated by M1 pattern 412) over M0 conductive structures 372, 374, 376, 378, 382, 384, and 386. In this example, conductive structure 432 corresponds to a word line is electrically coupled to the gate structures of the corresponding memory cells. In FIG. 4C, semiconductor device 400B includes gate structures 452, 454, 456, and 458 corresponding to the PO patterns in FIG. 3A. Also, in FIG. 4C, semiconductor device 400B includes conductive structure 432, 434, 436, 444, and 448 (corresponding to “M1” in the legend and as indicated by M1 patterns 412, 414, 416, 424, and 428) over the M0 conductive structures (e.g., M0 conductive structure 382). In this example, conductive structure 432 corresponds to a first word line electrically coupled to gate structures 452 and 454 through one or more via structures in a peripheral region outside the corresponding memory cell, and conductive structure 434 corresponds to a second word line electrically coupled to gate structures 456 and 458 through one or more other via structures in the peripheral region outside the corresponding memory cell. In this example, gate structures 452 and 454 are also configured to function as the first word line, and gate structures 456 and 458 are also configured to function as the second word line. In this example, conductive structure 436 corresponds to yet another word line of another set of memory cells, and conductive structures 444 and 448 correspond to different bit lines.

In view of the examples in FIGS. 4A-4C, in some embodiments, a semiconductor device (e.g., semiconductor device 400B) includes a memory cell array, a first conductive structure (e.g., gate structures 452 and/or 454) configured to carry a first control signal (e.g., a word line signal) for an operation of a set of memory cells of the memory cell array, and a second conductive structure (e.g., M1 conductive structure 432) electrically coupled to the first conductive structure and configured to carry the first control signal for the operation of the set of memory cells. In some embodiments, memory cells of the set of memory cells are arranged along a first horizontal direction (e.g., the Y direction), and the first conductive structure and the second conductive structure extend along the first horizontal direction.

In view of the examples in FIGS. 4A-4C, in some embodiments, the first conductive structure and the second conductive structure are spaced apart in a vertical direction (e.g., the Z direction). In some embodiments, the first conductive structure corresponds to a gate structure over a substrate of the semiconductor device, and the second conductive structure is included in a metallization layer (e.g., M1 layer) over the first conductive structure and over the substrate of the semiconductor device. In some embodiments, based on having multiple conductive structures configured to carry the same control signal (e.g., a word line signal in this example), the resistance of the corresponding signal line (e.g., a word line in this example) is further reduced. In some embodiments, the area occupied by each one of the conductive structures indicated by M1 patterns 422, 424, 426, and 428 for corresponding bit lines are reducible in order to further reduce the capacitance thereof.

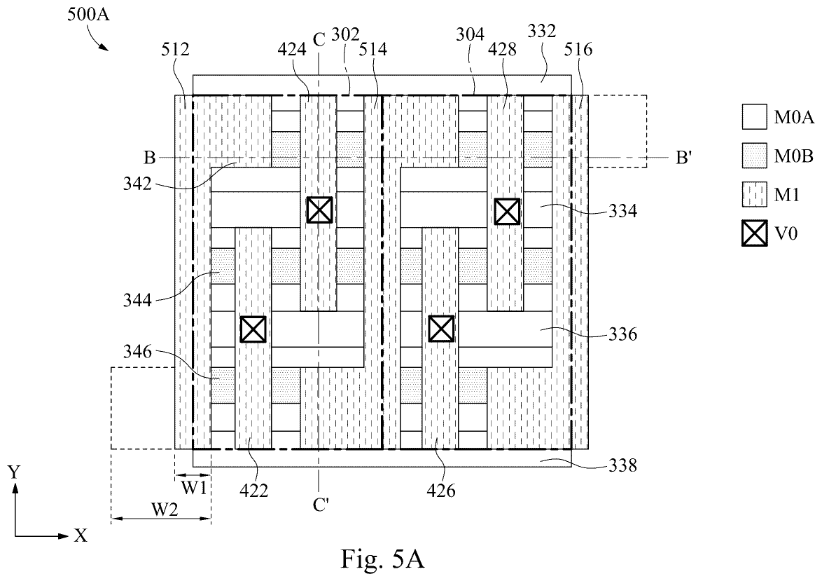

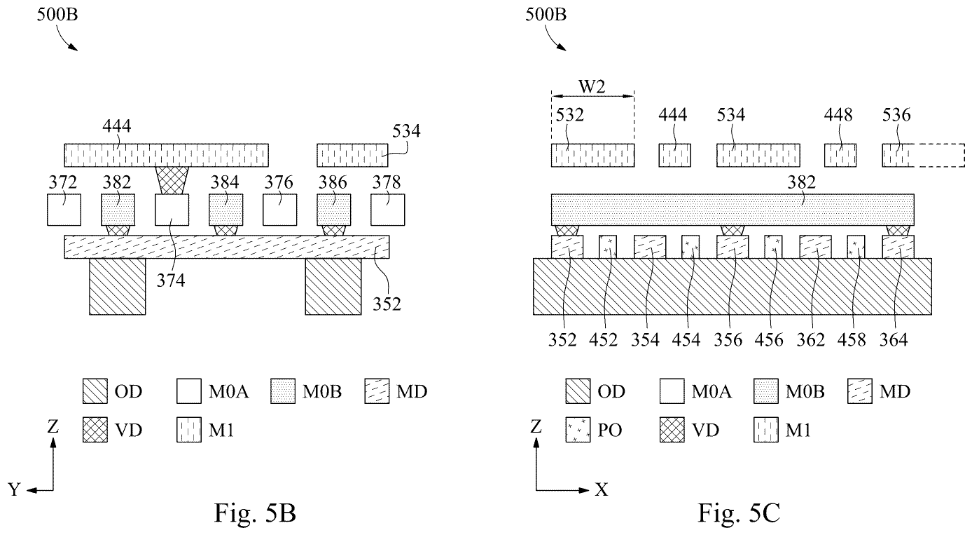

FIG. 5A is a layout diagram of a portion of a third layout example 500A, in accordance with some embodiments. In some embodiments, third layout example 500A is a variation of second layout example 400A, and incorporates the portions in FIGS. 3A-3B and 4A. In FIG. 5A, various layout patterns that are the same or similar to those in FIGS. 3A-3B and 4A are represented using the same legend and given the same reference numbers, and the description thereof is simplified or omitted.

Compared to the example in FIG. 4A, third layout example 500A includes M1 patterns 512, 514, and 516 (corresponding to “M1” in the legend) in place of M1 patterns 412, 414, and 416. In FIG. 5A, M1 pattern 512 is indicative of a conductive structure corresponding to a first word line electrically coupled to the memory cells represented by the two-unit cell 302; and M1 pattern 514 is indicative of a conductive structure corresponding to a second word line electrically coupled to the memory cells represented by the two-unit cell 304. In FIG. 5A, M1 patterns 512 and 516 have the same shape as M1 pattern 514, with dashed-line portions indicating the portions outside two-unit cells 302 and 304.

Taking M1 pattern 512 as an example, M1 pattern 512 includes at least a portion (e.g., a central portion along the Y direction) having a first line width W1 along the X direction that is equal to or greater than a default line width associated with the metallization layer (e.g., M1 layer). M1 pattern 512 further includes at least a portion (e.g., an end portion above the central portion or an end portion below the central portion with respect to the Y direction) having a second line width W2 along the X direction and greater than first line width W1.

FIGS. 5B-5C are cross-sectional views of a semiconductor device 500B that includes the memory device based on third layout example 500A in FIG. 5A, which is further based on the examples in FIGS. 3A-3B and 4A, in accordance with some embodiments. FIG. 5B corresponds to a cross-sectional view taken along a third reference line C-C′ in FIG. 5A. FIG. 5C corresponds to a cross-sectional view taken along the second reference line B-B′ in FIGS. 3A-3B and 5A. In FIGS. 5B-5C, various structures are represented using the same legend as the corresponding layout patterns in FIGS. 3A-3B, 4A, and 5A, and the description thereof is simplified or omitted. Also, FIGS. 5B-5C are simplified cross-sectional views, and various features of semiconductor device 500B are simplified or omitted in FIGS. 5B-5C.

In FIG. 5B, semiconductor device 500B includes conductive structures 444 and 534 (corresponding to “M1” in the legend and as indicated by M1 patterns 424 and 514). In this example, conductive structure 444 corresponds to a bit line, and conductive structure 534 corresponds to a word line. In FIG. 5C, semiconductor device 500B conductive structure 532, 534, 536, 444, and 448 (corresponding to “M1” in the legend and as indicated by M1 patterns 512, 514, 516, 424, and 428) over the M0 conductive structures (e.g., M0 conductive structure 382). In FIG. 5C and in view of FIG. 5A, the end portion of conductive structure 534 extends along the X direction across two M1 tracks and a space therebetween. Accordingly, the end portions of conductive structure 532, 534, and 536 have an enlarged line width (e.g., second line width W2) along the X direction.

In view of the examples in FIGS. 5A-5C, in some embodiments, a semiconductor device (e.g., semiconductor device 500B) includes a memory cell array, a first conductive structure (e.g., gate structures 452 and/or 454) configured to carry a first control signal (e.g., a word line signal) for an operation of a set of memory cells of the memory cell array, and a second conductive structure (e.g., M1 conductive structure 532) electrically coupled to the first conductive structure and configured to carry the first control signal for the operation of the set of memory cells.

In view of the examples in FIGS. 5A-5C, in some embodiments, the second conductive structure (e.g., M1 conductive structure 532) includes a first portion (e.g., a central portion thereof) having a first line width (e.g., first width W1) along the second horizontal direction that is equal to or greater than a default line width associated with the metallization layer, and a second portion (e.g., an end portion thereof) having a second line width (e.g., first width W2) along the second horizontal direction and greater than the first line width. In some embodiments, based on the conductive structures configured to carry a control signal (e.g., a word line signal in this example) having the widened line widths at certain portions thereof (e.g., the end portions), the resistance of the corresponding signal line (e.g., a word line in this example) is further reduced.

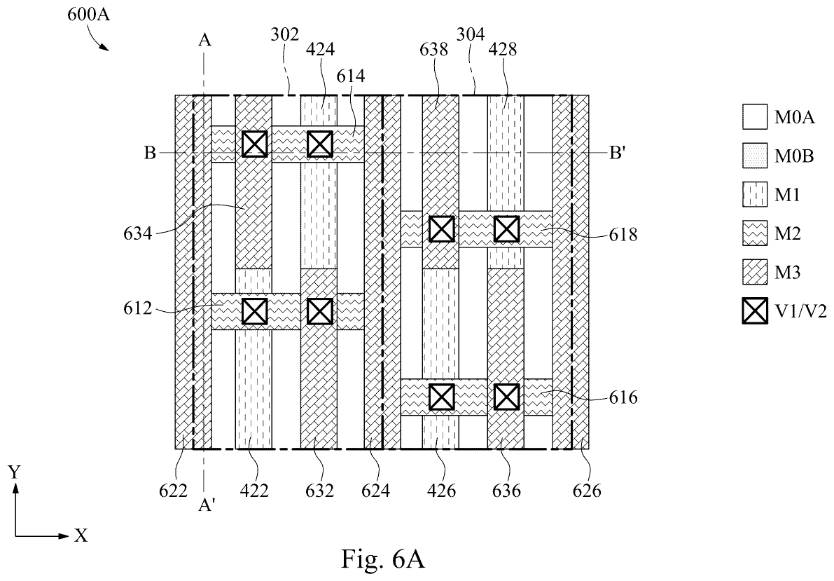

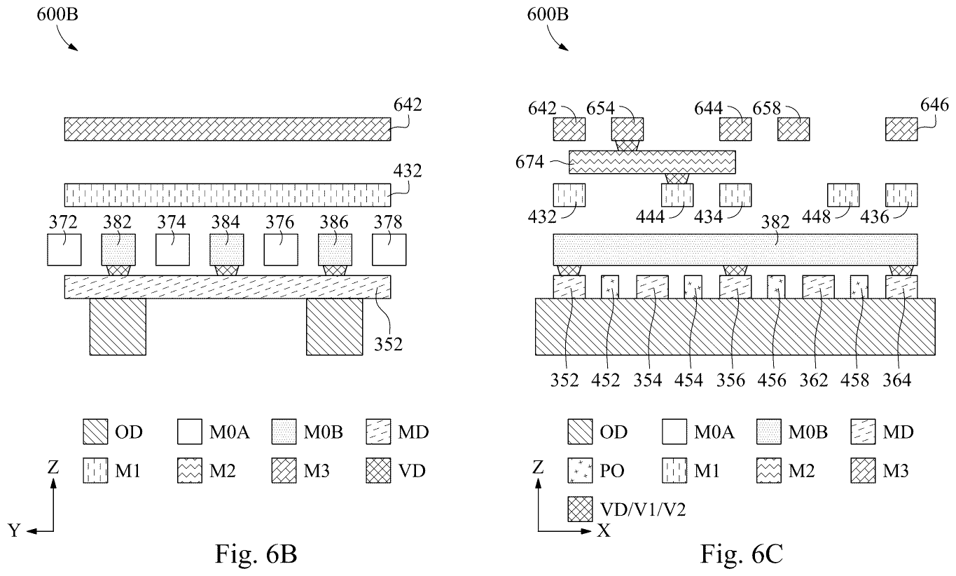

FIG. 6A is a layout diagram of a portion of a fourth layout example 600A, in accordance with some embodiments. In some embodiments, fourth layout example 600A is a variation of second layout example 400A, and incorporates the portions in FIGS. 3A-3B and 4A. In FIG. 6A, various layout patterns that are the same or similar to those in FIGS. 3A-3B and 4A are represented using the same legend and given the same reference numbers, and the description thereof is simplified or omitted.

Compared to the example in FIG. 4A, fourth layout example 600A includes M2 patterns 612, 614, 616, and 618 (corresponding to “M2” in the legend) indicative of conductive structures corresponding to various bit lines. In FIG. 5A, fourth layout example 600A further includes M3 patterns 622, 624, and 626 (corresponding to “M3” in the legend) indicative of conductive structures corresponding to various word lines and M3 patterns 632, 634, 636, and 638 (corresponding to “M3” in the legend) indicative of conductive structures corresponding to various bit lines.

In FIG. 6A, M3 pattern 622 is indicative of a conductive structure corresponding to a first word line electrically coupled to the memory cells represented by the two-unit cell 302; and M3 pattern 624 is indicative of a conductive structure corresponding to a second word line electrically coupled to the memory cells represented by the two-unit cell 304. In some embodiments, M3 pattern 626 is indicative of a conductive structure corresponding to yet another word line electrically coupled to the memory cells of another two-unit cell. Also, in this example, the conductive structures indicated by M3 pattern 632, M2 pattern 612, and M1 pattern 422 are electrically coupled by via structures indicated by corresponding V2 pattern and V1 pattern; the conductive structures indicated by M3 pattern 634, M2 pattern 614, and M1 pattern 424 are electrically coupled by via structures indicated by corresponding V2 pattern and V1 pattern; the conductive structures indicated by M3 pattern 636, M2 pattern 616, and M1 pattern 426 are electrically coupled by via structures indicated by corresponding V2 pattern and V1 pattern; and the conductive structures indicated by M3 pattern 638, M2 pattern 618, and M1 pattern 428 are electrically coupled by via structures indicated by corresponding V2 pattern and V1 pattern.

FIGS. 6B-6C are cross-sectional views of a semiconductor device 600B that includes the memory device based on fourth layout example 600A in FIG. 6A, which is further based on the examples in FIGS. 3A-3B and 4A, in accordance with some embodiments. FIG. 6B corresponds to a cross-sectional view taken along the first reference line A-A′ in FIGS. 3A-3B and 6A. FIG. 6C corresponds to a cross-sectional view taken along the second reference line B-B′ in FIGS. 3A-3B and 6A. In FIGS. 6B-6C, various structures are represented using the same legend as the corresponding layout patterns in FIGS. 3A-3B, 4A, and 6A, and the description thereof is simplified or omitted. Also, FIGS. 6B-6C are simplified cross-sectional views, and various structures of semiconductor device 600B are simplified or omitted in FIGS. 6B-6C.

In FIG. 6B, compared to semiconductor device 400B in FIGS. 4B-4C, semiconductor device 600B further includes conductive structure 642 (corresponding to “M3” in the legend and as indicated by M3 pattern 622). In this example, conductive structure 642 is electrically coupled to conductive structure 432 and corresponds to the same word line as conductive structure 432 as illustrated with reference to FIGS. 4B-4C. In FIG. 6C, compared to semiconductor device 400B in FIGS. 4B-4C, semiconductor device 600B includes conductive structures 642, 644, 646, 654, and 658 (corresponding to “M3” in the legend and as indicated by M3 patterns 622, 624, 626, 634, and 638) and a conductive structure 674 (corresponding to “M2” in the legend and as indicated by M2 pattern 614).

In this example, conductive structure 674 is electrically coupled to structure 444 through a V1 structure (corresponding to “V1” in the legend), and conductive structure 654 is electrically coupled to structure 674 through a V2 structure (corresponding to “V2” in the legend). In this example, conductive structures 444, 674, and 654 correspond to a bit line as conductive structure 374 in FIG. 5B. In this example, conductive structure 642 and conductive structure 432 correspond to a first word line electrically coupled to gate structures 452 and 454 through one or more via structures in a peripheral region outside the corresponding memory cell, and conductive structure 644 and conductive structure 434 correspond to a second word line electrically coupled to gate structures 456 and 458 through one or more other via structures in the peripheral region outside the corresponding memory cell. In this example, conductive structure 646 and conductive structure 436 correspond to yet another word line of another set of memory cells.

In view of the examples in FIGS. 6A-6C and FIGS. 4A-4C, in some embodiments, a semiconductor device includes one or more other conductive structures (e.g., conductive structure 642) electrically coupled to the first conductive structure (e.g., gate structures 456 and 458) and the second conductive structure (e.g., conductive structure 432), and extending along the first horizontal direction (e.g., the Y direction). In this example, the second conductive structure and the one or more other conductive structures are at different metallization layers over the substrate of the semiconductor device. In some embodiments, based on multiple parallel conductive structures electrically coupled together and configured to carry the same control signal (e.g., a word line signal in this example), the resistance of the corresponding signal line (e.g., a word line in this example) is further reduced.

In some embodiments, various parallel conductive structures that are electrically coupled together and correspond to a same control signal (e.g., a word line signal, a source line signal, or a bit line signal) are not limited to be at M1, M2, and/or M3 layers. In some embodiments, these parallel conductive structures arranged in different metallization layers are within the scope of the present disclosure.

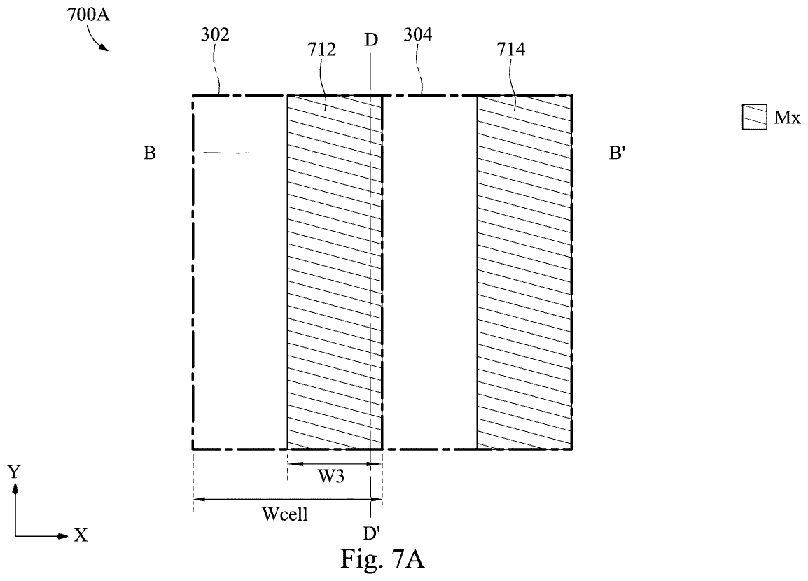

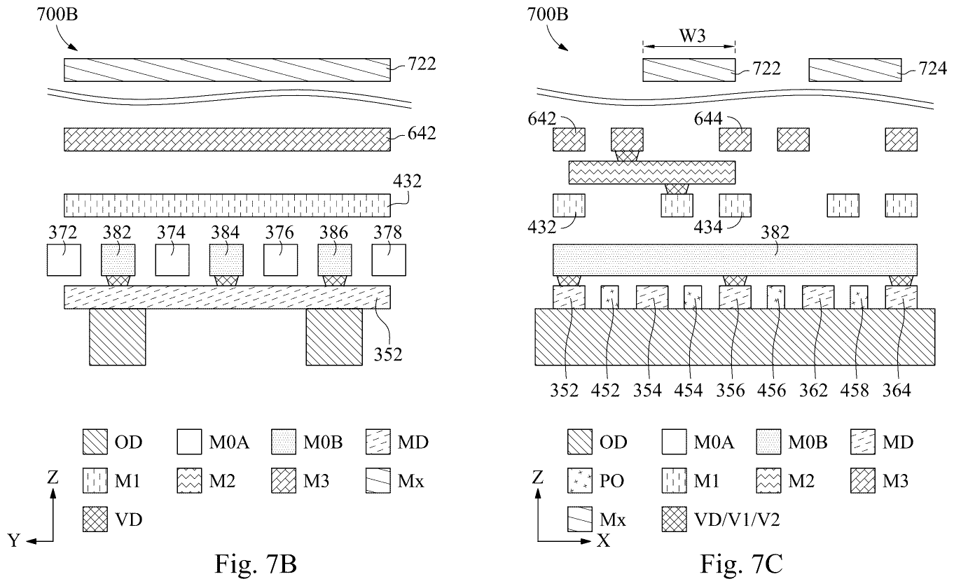

FIG. 7A is a layout diagram of a portion of a fifth layout example 700A, in accordance with some embodiments. In some embodiments, fifth layout example 700A is a variation of fourth layout example 600A, and incorporates the portions in FIGS. 3A-3B, 4A, and 6A. In FIG. 7A, various layout patterns that are the same or similar to those in FIGS. 3A-3B, 4A, and 6A are represented using the same legend and given the same reference numbers, and the description thereof is simplified or omitted.

Compared to the example in FIG. 6A, fifth layout example 700A further includes Mx patterns 712 and 714 (corresponding to “Mx” in the legend) indicative of conductive structures corresponding to various word lines at the Mx layer. In this example, subscript “x” indicates any of the metallization layers of the semiconductor device. In FIGS. 7A-7C as a non-limiting example, subscript “x” is greater than 3. In FIG. 7A, Mx pattern 712 is indicative of a conductive structure corresponding to a first word line electrically coupled to the memory cells represented by the two-unit cell 302; and Mx pattern 714 is indicative of a conductive structure corresponding to a second word line electrically coupled to the memory cells represented by the two-unit cell 304. In view of the example in FIGS. 6A-6C, the conductive structures indicated by Mx pattern 712 and M3 pattern 622 are electrically coupled by corresponding via structures; and the conductive structures indicated by Mx pattern 714 and M3 pattern 624 are electrically coupled by corresponding via structures.

In some embodiments, each memory cell has a cell width Wcell along the X horizontal direction. Moreover, the conductive structure indicated by Mx pattern 712 has a line width W3 along the X direction. In this example, in response to an adjacent conductive structure (e.g., indicated by Mx pattern 714) configured to carry another control signal of a same type (e.g., another word line signal) and the adjacent conductive structure (e.g., indicated by Mx pattern 714) and the conductive structure indicated by Mx pattern 712 being at a same metallization layer (e.g., Mx layer), line width W3 ranges from a default line width associated with the metallization layer to a difference between cell width Wcell and a minimal line space associated with the metallization layer such that every memory cell would be able to have a corresponding widened signal line (e.g., word line) conductive structures in that metallization layer. In some embodiments, line width W3 is set to be half of cell width Wcell.

FIGS. 7B-7C are cross-sectional views of a semiconductor device 700B that includes the memory device based on fifth layout example 700A in FIG. 7A, which is further based on the examples in FIGS. 3A-3B, 4A, and 6A, in accordance with some embodiments. FIG. 7B corresponds to a cross-sectional view taken along a fourth reference line D-D′ in FIG. 7A. FIG. 7C corresponds to a cross-sectional view taken along the second reference line B-B′ in FIGS. 3A-3B and 7A. In FIGS. 7B-7C, various structures are represented using the same legend as the corresponding layout patterns in FIGS. 3A-3B, 4A, and 6A, and the description thereof is simplified or omitted. Also, FIGS. 7B-7C are simplified cross-sectional views, and various structures of semiconductor device 700B are simplified or omitted in FIGS. 7B-7C.

In FIG. 7B, compared to semiconductor device 600B in FIG. 6B-6C, semiconductor device 700B further includes conductive structure 722 (corresponding to “Mx” in the legend and as indicated by Mx pattern 712). In FIG. 7C, compared to semiconductor device 600B in FIG. 6B-6C, semiconductor device 700B includes conductive structures 722 and 724 (corresponding to “Mx” in the legend and as indicated by Mx patterns 712 and 714). In this example, conductive structure 722, conductive structure 642, and conductive structure 432 correspond to a first word line electrically coupled to gate structures 452 and 454 through one or more via structures in a peripheral region outside the corresponding memory cell; and conductive structure 724, conductive structure 644, and conductive structure 434 correspond to a second word line electrically coupled to gate structures 456 and 458 through one or more other via structures in the peripheral region outside the corresponding memory cell.

In view of the examples in FIGS. 7A-7C, FIGS. 6A-6C, and FIGS. 4A-4C, a metallization layer is usable for additional, widened conductive structures to carry the same type of control signals (e.g., word line signals in this example). In some embodiments, the line width of these additional conductive structures is widened as long as they are still suitable to be arranged in the same metallization layer. In some embodiments, based on multiple parallel conductive structures are electrically coupled together and configured to carry the same control signal (e.g., a word line signal in this example), as well as additional, widened conductive structures based on the example in FIGS. 7A-7C, the resistance of the corresponding signal line (e.g., a word line in this example) is further reduced.

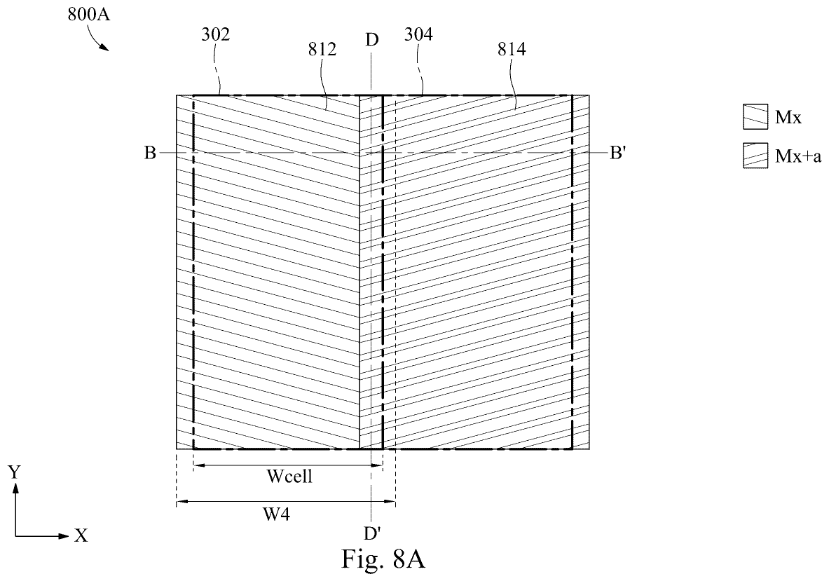

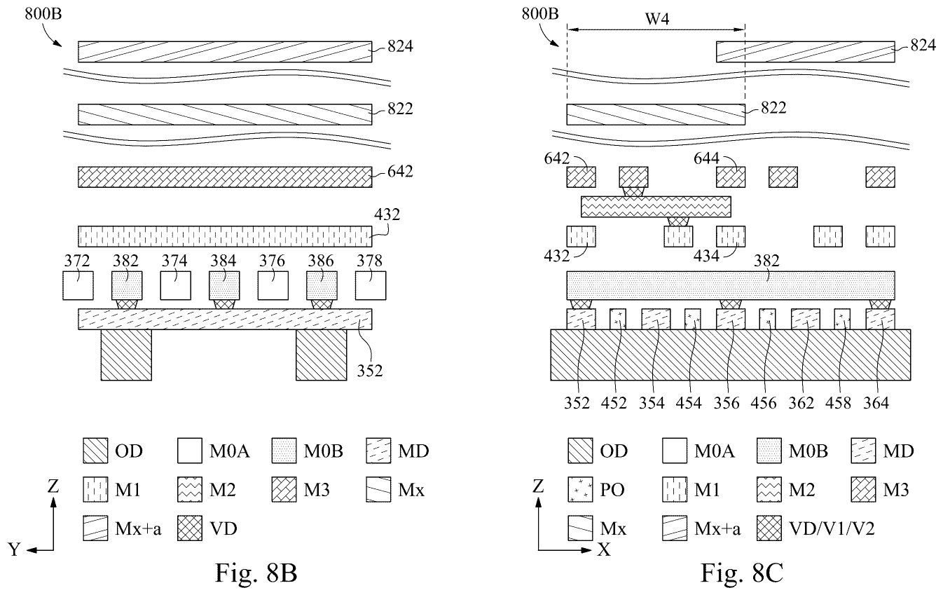

FIG. 8A is a layout diagram of a portion of a sixth layout example 800A, in accordance with some embodiments. In some embodiments, sixth layout example 800A is another variation of fourth layout example 600A, and incorporates the portions in FIGS. 3A-3B, 4A, and 6A. In FIG. 8A, various layout patterns that are the same or similar to those in FIGS. 3A-3B, 4A, and 6A are represented using the same legend and given the same reference numbers, and the description thereof is simplified or omitted.

Compared to the example in FIG. 6A, sixth layout example 800A further includes a Mx pattern 812 (corresponding to “Mx” in the legend) indicative of a conductive structure corresponding to a word line at the Mx metallization layer; and a Mx+a pattern 814 (corresponding to “Mxta” in the legend) indicative of a conductive structure corresponding to another word line at the Mx+a metallization layer. In this example, subscript “x” indicates any of the metallization layers of the semiconductor device, and subscript “x+a” indicates any of the metallization layers of the semiconductor device above the Mx layer. In FIGS. 8A-8C as a non-limiting example, subscript “x” is greater than 3, and “a” is a positive, even integer. In FIG. 8A, Mx pattern 812 is indicative of a conductive structure corresponding to a first word line electrically coupled to the memory cells represented by the two-unit cell 302; and Mx+a pattern 814 is indicative of a conductive structure corresponding to a second word line electrically coupled to the memory cells represented by the two-unit cell 304. In view of the example in FIGS. 6A-6C, the conductive structures indicated by Mx pattern 812 and M3 pattern 622 are electrically coupled by via structures; and the conductive structures indicated by Mx+a pattern 814 and M3 pattern 624 are electrically coupled by via structures.

In some embodiments, each memory cell has a cell width Wcell along the X horizontal direction. Moreover, the conductive structure indicated by Mx pattern 812 has a line width W4 along the X direction. In this example, in response to an adjacent conductive structure (e.g., indicated by Mx+a pattern 814) configured to carry another control signal of a same type (e.g., another word line signal) and the adjacent conductive structure and the conductive structure indicated by Mx pattern 812 being at different metallization layers (e.g., Mx layer and Mx+a layer), line width W4 is equal to or greater than the cell Wcell. In some embodiments, line width W4 is set to be at least 1.2 times the cell width Wcell.

FIGS. 8B-8C are cross-sectional views of a semiconductor device 800B that includes the memory device based on sixth layout example 800A in FIG. 8A, which is further based on the examples in FIGS. 3A-3B, 4A, and 6A, in accordance with some embodiments. FIG. 8B corresponds to a cross-sectional view taken along a fourth reference line D-D′ in FIG. 8A. FIG. 8C corresponds to a cross-sectional view taken along the second reference line B-B′ in FIGS. 3A-3B and 8A. In FIGS. 8B-8C, various structures are represented using the same legend as the corresponding layout patterns in FIGS. 3A-3B, 4A, and 6A, and the description thereof is simplified or omitted. Also, FIGS. 8B-8C are simplified cross-sectional views, and various structures of semiconductor device 800B are simplified or omitted in FIGS. 8B-8C.

In FIGS. 8B-8C, compared to semiconductor device 600B in FIG. 6B-6C, semiconductor device 800B further includes conductive structure 822 (corresponding to “Mx” in the legend and as indicated by Mx pattern 812) and conductive structure 824 (corresponding to “Mxta” in the legend and as indicated by Mx+a pattern 814). In this example, conductive structure 822, conductive structure 642, and conductive structure 432 correspond to a first word line electrically coupled to gate structures 452 and 454 through one or more via structures in a peripheral region outside the corresponding memory cell; and conductive structure 824, conductive structure 644, and conductive structure 434 correspond to a second word line electrically coupled to gate structures 456 and 458 through one or more other via structures in the peripheral region outside the corresponding memory cell.

In view of the examples in FIGS. 8A-8C, FIGS. 6A-6C, and FIGS. 4A-4C, two or more metallization layers are usable for additional conductive structures to carry the same type of control signals (e.g., word line signals in this example). In some embodiments, the line width of these additional conductive structures is widened to be equal to or greater than a cell width. In some embodiments, based on multiple parallel conductive structures are electrically coupled together and configured to carry the same control signal (e.g., a word line signal in this example), as well as additional, widened conductive structures based on the example in FIGS. 8A-8C, the resistance of the corresponding signal line (e.g., a word line in this example) is further reduced.

In some embodiments, various parallel conductive structures that are electrically coupled together and correspond to a same control signal (e.g., a word line signal, a source line signal, or a bit line signal) are implemented based on the examples in FIGS. 3A-8C individually or based on a combination thereof.

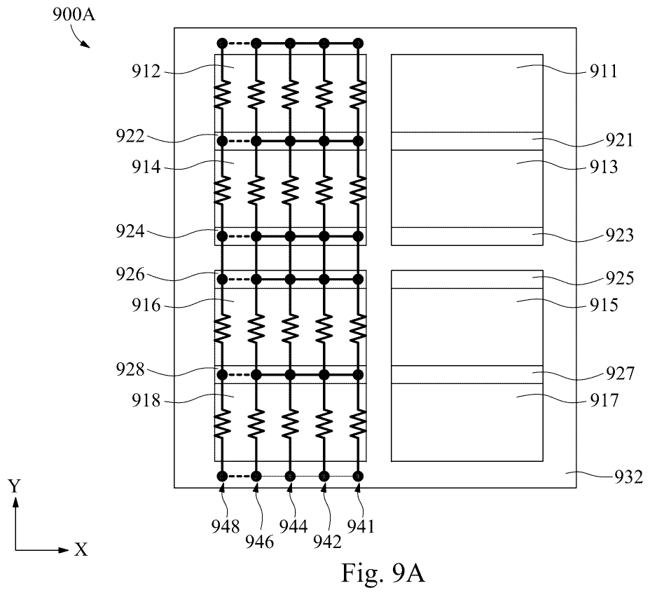

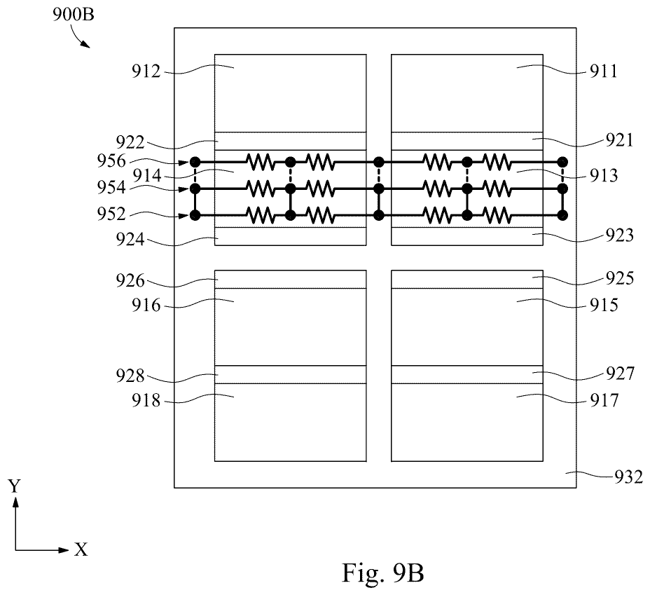

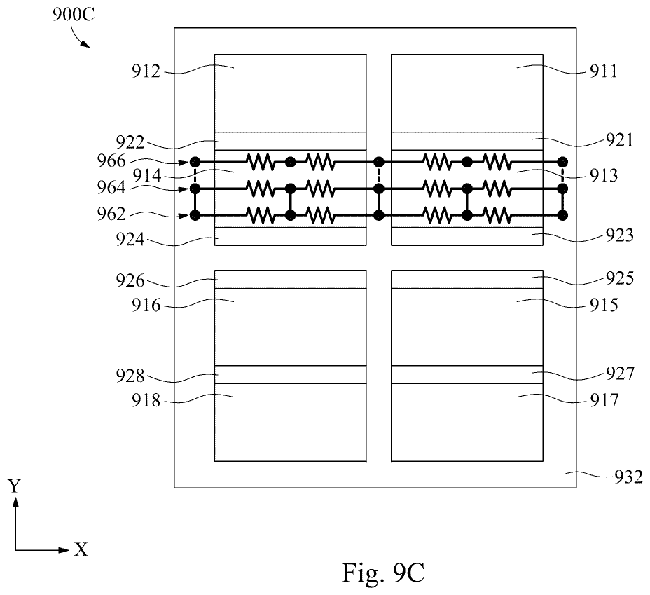

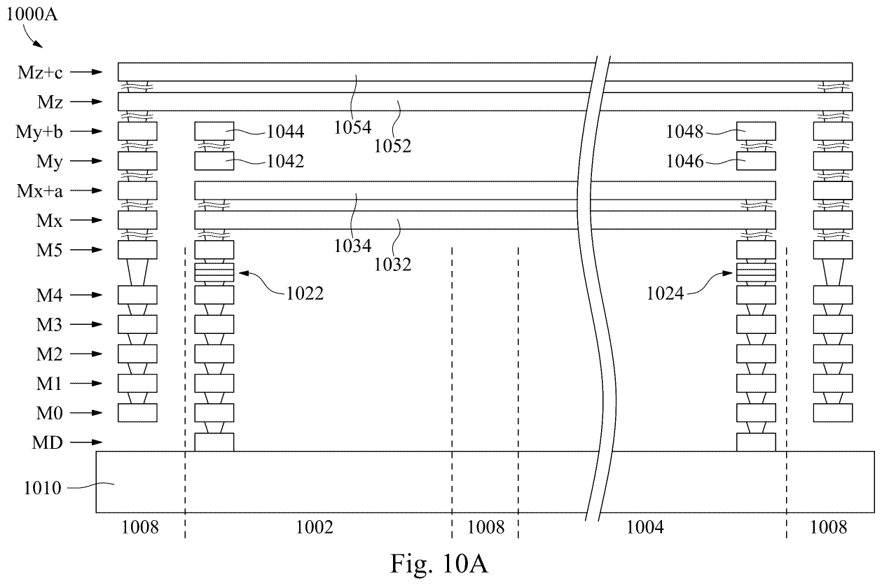

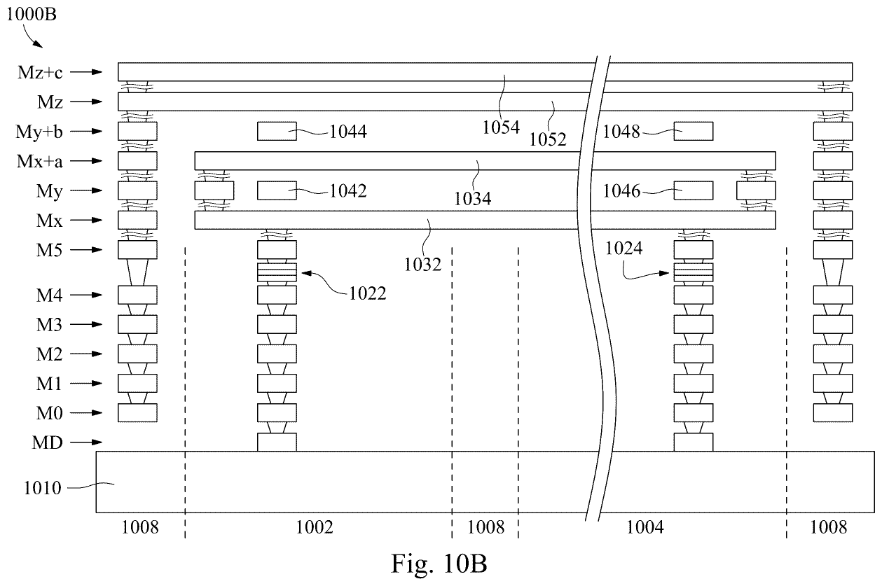

FIG. 9A is a plan view of a floor plan example 900A of a semiconductor device that includes a memory device, in accordance with some embodiments. Floor plan example 900A is a simplified floor plan indicating how the resistance of a particular signal line (e.g., a word line in this example) in a memory device is reduced based on one or more of the examples in FIGS. 3A-8C.

Floor plan example 900A includes memory cell regions 911-918 in which memory cells are placed and peripheral regions 921-928 in which electrical components for peripheral circuitry are placed. Moreover, floor plan example 900A includes a buffer region 932 surrounding memory cell regions 911-918 and peripheral regions 921-928. In some embodiments, the memory cells placed in memory cell regions 911-918 correspond to volatile memory cells, such as DRAM cells or SRAM cells. In some embodiments, the memory cells placed in memory cell regions 911-918 correspond to non-volatile memory cells, such as floating-gate memory cells, FRAM cells, MRAM cells, PCM cells, or RRAM cells. In some embodiments, the memory cells are formed in an FEOL portion of the resulting semiconductor device. In some embodiments, the memory cells are formed in a BEOL portion of the resulting semiconductor device.

In FIG. 9A, a word line includes conductive structures 941, 942, 944, 946, and 948 extending along the Y direction. In this example, conductive structures 941, 942, 944, 946, and 948 are electrically coupled together based on via structures and/or other conductive structures in the peripheral regions 922, 924, 926, and 928 and/or the buffer region 932. In some embodiments, in response to the memory cells are formed in the FEOL portion, conductive structure 941 corresponds the gate structures of the associated memory cells, and conductive structures 942, 944, 946, and 948 are at different metallization layers. In some embodiments, in response to the memory cells are formed in the BEOL portion, conductive structures 941, 942, 944, 946, and 948 are at different metallization layers. As such, the word line in this example includes parallel conductive structures at least four different metallization layers. In some embodiments, the word line includes parallel conductive structures at least two different metallization layers. In some embodiments, based on multiple parallel conductive structures electrically coupled together and configured to carry the same control signal (e.g., a word line signal in this example), the resistance of the corresponding signal line (e.g., a word line in this example) is further reduced.

FIG. 9B is a plan view of a floor plan example 900B of a semiconductor device that includes a memory device, in accordance with some embodiments. Floor plan example 900B is a simplified floor plan indicating how the resistance of a particular signal line (e.g., a source line in this example) in a memory device is reduced based on one or more of the examples in FIGS. 3A-8C. Moreover, components in FIG. 9B that are the same or similar to those in FIG. 9A are given the same reference numbers, and the description thereof is simplified or omitted.

In FIG. 9B, a source line includes conductive structures 952, 954, and 956 extending along the X direction. In this example, conductive structures 952, 954, and 956 are electrically coupled together based on via structures and/or other conductive structures in memory cell regions 913 and 914 and/or the buffer region 932. In some embodiments, conductive structures 952, 954, and 956 are at different metallization layers. As such, the source line in this example includes parallel conductive structures at least three different metallization layers. In some embodiments, the source line includes parallel conductive structures at least two different metallization layers. In some embodiments, based on multiple parallel conductive structures electrically coupled together and configured to carry the same control signal (e.g., a source line signal in this example), the resistance of the corresponding signal line (e.g., a source line in this example) is further reduced.

FIG. 9C is a plan view of a floor plan example 900C of a semiconductor device that includes a memory device, in accordance with some embodiments. Floor plan example 900C is a simplified floor plan indicating how the resistance of a particular signal line (e.g., a bit line in this example) in a memory device is reduced based on one or more of the examples in FIGS. 3A-8C. Moreover, components in FIG. 9C that are the same or similar to those in FIG. 9A are given the same reference numbers, and the description thereof is simplified or omitted.

In FIG. 9C, a bit line includes conductive structures 962, 964, and 966 extending along the X direction. In this example, conductive structures 962, 964, and 966 are electrically coupled together based on via structures and/or other conductive structures in memory cell regions 913 and 914 and/or the buffer region 932. In some embodiments, conductive structures 962, 964, and 966 are at different metallization layers. As such, the bit line in this example includes parallel conductive structures at least three different metallization layers. In some embodiments, the bit line includes parallel conductive structures at least two different metallization layers. In some embodiments, based on multiple parallel conductive structures electrically coupled together and configured to carry the same control signal (e.g., a bit line signal in this example), the resistance of the corresponding signal line (e.g., a bit line in this example) is further reduced.

FIG. 10A is a cross-sectional view of a semiconductor device example 1000A that includes parallel conductive structures at different metallization layers for a memory device, in accordance with some embodiments. In this example, semiconductor device example 1000A includes memory cell regions 1002 and 1004 in which memory cells are arranged, and a buffer region 1008 surrounding memory cell regions 1002 and 1004. In FIG. 10A, semiconductor device example 1000A includes a substrate 1010 that corresponds to substrate 210 in FIG. 2, a metal-to-drain/source (MD) structure layer that corresponds to MD layer in FIG. 2, and metallization layers M0-M5, Mx, Mxta, My, My+b, Mz, and Mz+c that correspond to various metallization layers in FIG. 2. In this example, subscript x, x+a, y, y+b, z, and z+c correspond to positive integers.

In FIG. 10A, within the memory cell regions 1002 and 1004, RRAM memory cells 1022 and 1024 are formed between M4 layer and M5 layer. In this example, a conductive structure 1032 at Mx layer and a conductive structure 1034 at Mx+a layer are electrically coupled together and configured to carry a bit line signal. In this example, a conductive structure 1042 at My layer and a conductive structure 1044 at My+b layer are electrically coupled together and configured to carry a first word line signal; and a conductive structure 1046 at My layer and a conductive structure 1048 at My+b layer are electrically coupled together and configured to carry a second word line signal. Also, in this example, a conductive structure 1052 at Mz layer and a conductive structure 1054 at Mztc layer are electrically coupled together and configured to carry a source line signal.

In FIG. 10A, Mz+c layer and Mz layer are above My+b layer and My layer, which are above Mx+a layer and Mx layer. In some embodiments, as subscript x, x+a, y, y+b, z, and ztc correspond to positive integers and are not limited to any given order, the order of Mx, Mx+a, My, My+b, Mz, and Mztc layers are not limited to the example in FIG. 10A.

For example, FIG. 10B is a cross-sectional view of another semiconductor device example 1000B that includes parallel conductive structures at different metallization layers for a memory device, in accordance with some embodiments. Components in FIG. 10B that are the same or similar to those in FIG. 10A are given the same reference number, and the description thereof are simplified or omitted. In FIG. 10B, compared to semiconductor device example 1000A, semiconductor device example 1000B includes Mx, Mx+a, My, My+b, Mz, and Mz+c layers arranged at a different order. In this example, My+b layer is above Mx+a layer, which is above My layer, which is above Mx layer.

In view of one or more examples presented above, in some embodiments, a semiconductor device includes a memory cell array (e.g., memory cell array 110 in FIG. 1), a first conductive structure configured to carry a first control signal (e.g., a word line signal, a bit line signal, or a source line signal) for an operation of a set of memory cells of the memory cell array, and a second conductive structure electrically coupled to the first conductive structure and configured to carry the first control signal for the operation of the set of memory cells of the memory cell array. In some embodiments, memory cells of the set of memory cells are arranged along a first horizontal direction (e.g., one of the X direction or Y direction). In some embodiments, the first conductive structure and the second conductive structure extend along the first horizontal direction, and the first conductive structure and the second conductive structure are spaced apart in a second horizontal direction (e.g., the other one of the X direction or Y direction), in a vertical direction (e.g., the Z direction), or both.

In some embodiments, as discussed based on the non-limiting example in FIGS. 3A-3D, the semiconductor device further includes a third conductive structure (e.g., drain/source structure 352) extending along the second horizontal direction and a plurality of via structures connecting the third conductive structure and the first conductive structure and the second conductive structure (e.g., conductive structures 382, 384, and/or 386). In some embodiments, the first conductive structure and the second conductive structure are included in a same metallization layer (e.g., M0 layer). In some embodiments, the third conductive structure corresponds to a drain/source terminal structure (e.g., MD layer) over a substrate (e.g., substrate 210 in FIG. 2) of the semiconductor device.

In some embodiments, as discussed based on the non-limiting example in FIGS. 4A-4C, the first conductive structure corresponds to a gate structure (e.g., gate structure 452 and/or gate structure 454) over a substrate of the semiconductor device. In some embodiments, the second conductive structure (e.g., conductive structure 432) is included in a metallization layer (e.g., M1 layer) over the first conductive structure and over the substrate of the semiconductor device.

In some embodiments, as discussed based on the non-limiting example in FIGS. 5A-5C, the second conductive structure (e.g., conductive structure 532) includes a first portion having a first line width (e.g., line width W1) along the second horizontal direction (e.g., the X direction) that is equal to or greater than a default line width associated with the metallization layer, and a second portion having a second line width (e.g., line width W2) along the second horizontal direction and greater than the first line width.

In some embodiments, each memory cell of the memory cell array has a cell width (e.g., cell width Wcell in FIGS. 7A and 8A) along the second horizontal direction (e.g., the X direction). In some embodiments, as discussed based on the non-limiting example in FIGS. 7A-7C, the second conductive structure (e.g., conductive structure 722) has a line width (e.g., line width W3) along the second horizontal direction. In some embodiments, in response to an adjacent conductive structure (e.g., conductive structure 724) configured to carry a second control signal of a same type as the first control signal and the adjacent conductive structure and the second conductive structure being at a same metallization layer, the line width (e.g., line width W3) ranges from a default line width associated with the metallization layer to a difference between the cell width and a minimal line space associated with the metallization layer. In some embodiments, as discussed based on the non-limiting example in FIGS. 8A-8C, the second conductive structure (e.g., conductive structure 822) has a line width (e.g., line width W4) along the second horizontal direction. In some embodiments, in response to an adjacent conductive structure (e.g., conductive structure 824) and the second conductive structure being at different metallization layers, the line width (e.g., line width W4) is equal to or greater than the cell width (e.g., cell width Wcell).

In some embodiments, as discussed based on the non-limiting examples in FIGS. 4A-10B, the first conductive structure and the second conductive structure are at different metallization layers over a substrate of the semiconductor device. In some embodiments, as discussed based on the non-limiting examples in FIGS. 6A-9C, the semiconductor device further includes one or more other conductive structures electrically coupled to the first conductive structure, and extending along the first horizontal direction. In some embodiments, the first conductive structure, the second conductive structure, and the one or more other conductive structures are at different metallization layers over the substrate of the semiconductor device.

In some embodiments, the first conductive structure and the second conductive structure correspond to a source line of the memory cell array, a bit line of the memory cell array, or a word line of the memory cell array. in some embodiments, the memory cell array includes memory cells that are volatile memory cells including DRAM cells or SRAM cells, or non-volatile memory cells including floating-gate memory cells, FRAM cells, MRAM cells, PCM cells, or RRAM cells.

In some embodiments, as discussed based on the non-limiting examples in FIGS. 10A-10B, in addition to the first conductive structure (e.g., conductive structure 1032) and the second conductive structure (e.g., conductive structure 1034) configured to carry the first control signal (e.g., a bit line signal), the semiconductor device further includes a third conductive structure (e.g., conductive structure 1042) configured to carry a second control signal (e.g., a word line signal) for an operation of a second set of memory cells of the memory cell array and a fourth conductive structure (e.g., conductive structure 1044) electrically coupled to the third conductive structure and configured to carry the second control signal for the operation of the second set of memory cells of the memory cell array. In some embodiments, the third conductive structure and fourth second conductive structure extend along the second horizontal direction and are spaced apart in the first horizontal direction, in the vertical direction, or both. In some embodiments, the first conductive structure is included in a first metallization layer (e.g., Mx layer in FIGS. 10A-10B) over the memory cell array, the second conductive structure is included in a second metallization layer (e.g., Mx+a layer in FIGS. 10A-10B) over the first metallization layer, the third conductive structure is included in a third metallization layer (e.g., My layer in FIGS. 10A-10B) over the first conductive structure, and the fourth conductive structure is included in a fourth metallization layer (e.g., Mytb layer in FIGS. 10A-10B) over the third conductive structure. In some embodiments, the third conductive structure is over the second conductive structure as discussed based on the non-limiting example in FIG. 10A. In some embodiments, the third conductive structure is under the second conductive structure as discussed based on the non-limiting example in FIG. 10B.

Also, in view of one or more examples presented above, in some embodiments, a semiconductor device includes a memory cell array (e.g., memory cell array 110 in FIG. 1) and a first plurality of conductive structures (e.g., conductive structures 1032 and 1034) included in a first plurality of metallization layers over the memory cell array. In some embodiments, the first plurality of conductive structures is electrically coupled to one another and configured to carry a first control signal (e.g., a bit line signal) for an operation of a first set of memory cells of the memory cell array. in some embodiments, memory cells of the first set of memory cells are arranged along a first horizontal direction, and each one of the first plurality of conductive structures extends along the first horizontal direction and overlapping the first set of memory cells.

In some embodiments, the semiconductor device further includes a second plurality of conductive structures (e.g., conductive structures 1042 and 1044) included in a second plurality of metallization layers over the memory cell array. In some embodiments, the second plurality of conductive structures is electrically coupled to one another and configured to carry a second control signal for an operation of a second set of memory cells of the memory cell array. in some embodiments, memory cells of the second set of memory cells are arranged along a second horizontal direction, and each one of the second plurality of conductive structures extends along the second horizontal direction.

In some embodiments, the semiconductor device further includes a third plurality of conductive structures (e.g., conductive structures 1052 and 1054) included in a third plurality of metallization layers over the memory cell array. In some embodiments, the third plurality of conductive structures is electrically coupled to one another and configured to carry a third control signal for the operation of the first set of memory cells of the memory cell array. In some embodiments, each one of the third plurality of conductive structures extends along the first horizontal direction.

In some embodiments, the first plurality of conductive structures corresponds to a bit line of the memory cell array, the second plurality of conductive structures corresponds to a word line of the memory cell array, and the third plurality of conductive structures corresponds to a source line of the memory cell array. In some other embodiments, the first plurality of conductive structures corresponds to the source line of the memory cell array, the second plurality of conductive structures corresponds to the word line of the memory cell array, and the third plurality of conductive structures corresponds to the bit line of the memory cell array.

In some embodiments, as discussed based on the non-limiting example in FIG. 10A, the first plurality of conductive structures, the second plurality of conductive structures, and the third plurality of conductive structures are arranged one over another along a vertical direction. In some embodiments, as discussed based on the non-limiting example in FIG. 10B, at least one of the first plurality of conductive structures is between two of the second plurality of conductive structures along a vertical direction, and/or at least one of the second plurality of conductive structures is between two of the third plurality of conductive structures along the vertical direction.

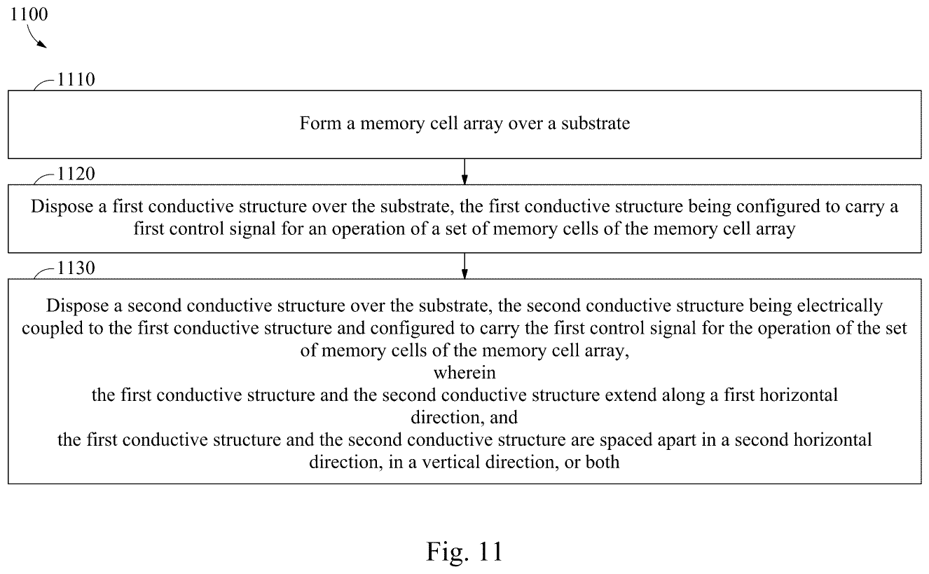

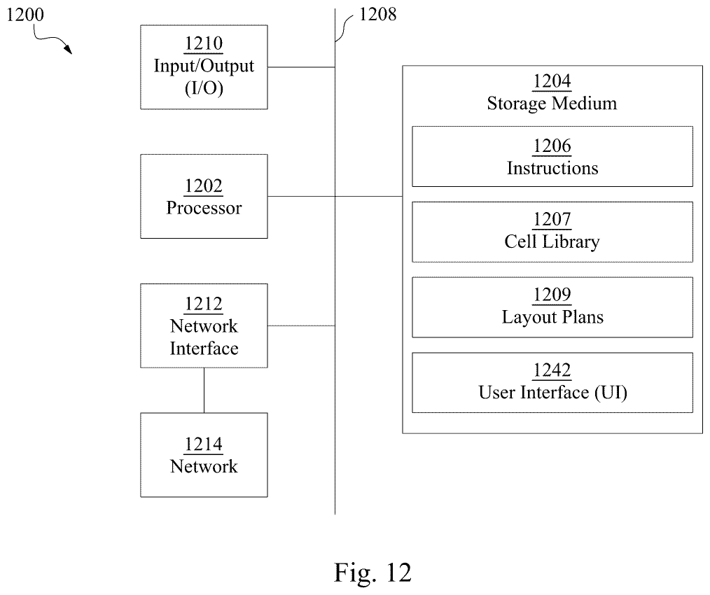

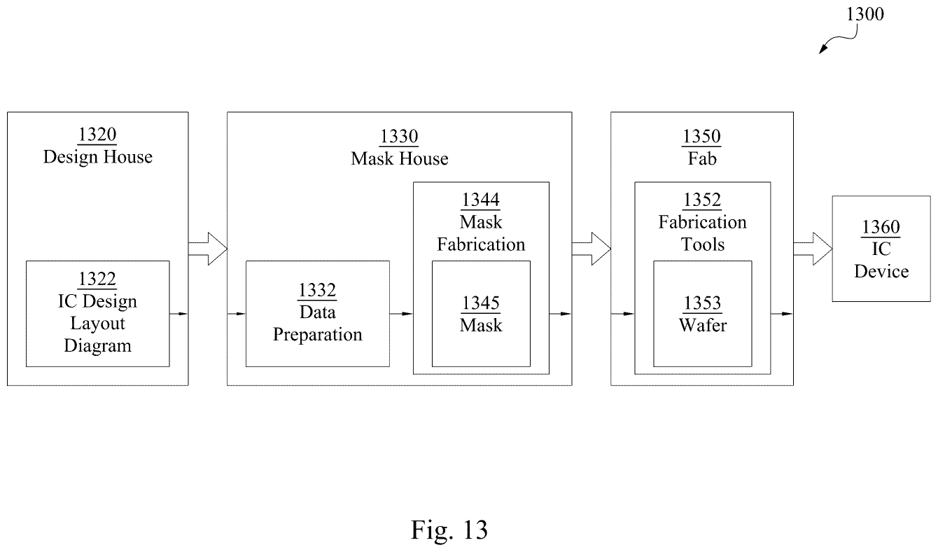

FIG. 11 is a flowchart of a method 1100 of manufacturing a semiconductor device, in accordance with some embodiments. In some embodiments, the semiconductor device based on method 1100 corresponds to the examples in FIGS. 3A-10B in view of the configurations in FIGS. 1-2. In some embodiments, method 1100 is performed in conjunction with an IC manufacturing system as discussed with respect to the IC manufacturing system 1300 in FIG. 13. In some embodiments, the semiconductor device is designed based on an EDA system as discussed with respect to the EDA system in FIG. 12. Method 1100 includes blocks 1110-1130.

At block 1110, a memory cell array is formed over a substrate. In some embodiments, block 1110 includes forming volatile memory cells including DRAM cells or SRAM cells. In some embodiments, block 1110 includes forming non-volatile memory cells including floating-gate memory cells, FRAM cells, MRAM cells, PCM cells, or RRAM cells.

At block 1120, a first conductive structure is disposed over the substrate. In some embodiments, the first conductive structure is configured to carry a first control signal for an operation of a set of memory cells of the memory cell array.

At block 1130, a second conductive structure is disposed over the substrate. In some embodiments, the second conductive structure is electrically coupled to the first conductive structure and configured to carry the first control signal for the operation of the set of memory cells of the memory cell array.

In some embodiments, memory cells of the set of memory cells are arranged along a first horizontal direction. In some embodiments, the first conductive structure and the second conductive structure extend along the first horizontal direction, and the first conductive structure and the second conductive structure are spaced apart in a second horizontal direction, in a vertical direction, or both. In some embodiments, the first control signal corresponds to a bit line signal, a word line signal, or a source line signal.

In some embodiments, in view of the non-limiting examples in FIGS. 3A-3D, method 1100 further includes forming a metallization layer including the first conductive structure and the second conductive structure, disposing a third conductive structure over the substrate and extending along the second horizontal direction, and disposing a plurality of via structures connecting the third conductive structure and the first conductive structure and the second conductive structure. In some embodiments, the disposing the third conductive structure includes forming a metal-to-drain/source (MD) structure as the third conductive structure.

In some embodiments, in view of the non-limiting examples in FIGS. 4A-4C, the disposing the first conductive structure includes forming a gate structure as the first conductive structure, and the disposing the second conductive structure includes forming a metallization layer over the first conductive structure and including the second conductive structure.

In some embodiments, in view of the non-limiting examples in FIGS. 5A-5C, the disposing the second conductive structure includes forming a first portion of the second conductive structure having a first line width (e.g., line width W1) along the second horizontal direction that is equal to or greater than a default line width associated with the metallization layer, and forming a second portion of the second conductive structure having a second line width (e.g., line width W2) along the second horizontal direction and being greater than the first line width.

In some embodiments, each memory cell of the memory cell array has a cell width (e.g., line width Wcell) along the second horizontal direction. In some embodiments, in view of the non-limiting examples in FIGS. 7A-7C, in response to an adjacent conductive structure configured to carry a second control signal of a same type as the first control signal and the adjacent conductive structure and the second conductive structure being at a same metallization layer, the disposing the second conductive structure includes forming the second conductive structure having a line width (e.g., line width W3) along the second horizontal direction, and the line width ranging from a default line width associated with the metallization layer to a difference between the cell width and a minimal line space associated with the metallization layer. In some embodiments, in view of the non-limiting examples in FIGS. 8A-8C, in response to the adjacent conductive structure and the second conductive structure being at different metallization layers, the disposing the second conductive structure includes forming the second conductive structure having the line width (e.g., line width W4) equal to or greater than the cell width.

In some embodiments, method 1100 includes forming two different metallization layers including the first conductive structure and the second conductive structure. In some embodiments, method 1100 further includes forming one or more other metallization layers including one or more other corresponding conductive structures. In some embodiments, the one or more other conductive structures are electrically coupled to the first conductive structure, and extend along the first horizontal direction.

FIG. 12 is a block diagram of an electronic design automation (EDA) system 1200 in accordance with some embodiments. In some embodiments, EDA system 1200 includes an automatic placement and routing (APR) system. Methods described herein in accordance with one or more embodiments are implementable, for example, using EDA system 1200, in accordance with some embodiments.

In some embodiments, EDA system 1200 is a general-purpose computing device including a hardware processor 1202 and a computer-readable storage medium 1204. Storage medium 1204, amongst other things, is encoded with, i.e., stores, computer program code 1206, i.e., a set of executable instructions. Execution of instructions 1206 by hardware processor 1202 represents (at least in part) an EDA tool which implements a portion or all of the methods described herein in accordance with one or more embodiments (hereinafter, the noted processes and/or methods).

Processor 1202 is electrically coupled to computer-readable storage medium 1204 via a bus 1208. Processor 1202 is also electrically coupled to an I/O interface 1210 by bus 1208. A network interface 1212 is also electrically connected to processor 1202 via bus 1208. Network interface 1212 is connected to a network 1214, so that processor 1202 and computer-readable storage medium 1204 are capable of connecting to external elements via network 1214. Processor 1202 is configured to execute computer program code 1206 encoded in computer-readable storage medium 1204 in order to cause system 1200 to be usable for performing a portion or all of the noted processes and/or methods. In one or more embodiments, processor 1202 is a CPU, a multi-processor, a distributed processing system, an application specific integrated circuit (ASIC), and/or a suitable processing unit.

In one or more embodiments, computer-readable storage medium 1204 is a non-transitory computer-readable storage medium including an electronic, magnetic, optical, electromagnetic, infrared, and/or a semiconductor system (or apparatus or device). For example, computer-readable storage medium 1204 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1204 includes a compact disk-read only memory (CD-ROM), a compact disk-read/write (CD-R/W), and/or a digital video disc (DVD).

In one or more embodiments, storage medium 1204 stores computer program code 1206 configured to cause system 1200 (where such execution represents (at least in part) the EDA tool) to be usable for performing a portion or all of the noted processes and/or methods. In one or more embodiments, storage medium 1204 also stores information which facilitates performing a portion or all of the noted processes and/or methods. In one or more embodiments, storage medium 1204 stores a cell library 1207 of standard cells including such standard cells as disclosed herein. In one or more embodiments, storage medium 1204 stores one or more layout plans 1209 corresponding to one or more layouts plans disclosed herein.

EDA system 1200 includes I/O interface 1210. I/O interface 1210 is coupled to external circuitry. In one or more embodiments, I/O interface 1210 includes a keyboard, keypad, mouse, trackball, trackpad, touchscreen, and/or cursor direction keys for communicating information and commands to processor 1202.

EDA system 1200 also includes network interface 1212 coupled to processor 1202. Network interface 1212 allows system 1200 to communicate with network 1214, to which one or more other computer systems are connected. Network interface 1212 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1200.

System 1200 is configured to receive information through I/O interface 1210. The information received through I/O interface 1210 includes one or more of instructions, data, design rules, libraries of standard cells, and/or other parameters for processing by processor 1202. The information is transferred to processor 1202 via bus 1208. EDA system 1200 is configured to receive information related to a UI through I/O interface 1210. The information is stored in computer-readable medium 1204 as user interface (UI) 1242.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1200. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 13 is a block diagram of an IC manufacturing system 1300, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1300.

In FIG. 13, IC manufacturing system 1300 includes entities, such as a design house 1320, a mask house 1330, and an IC manufacturer/fabricator (fab) 1350, that interact with one another in the design, development, and manufacturing cycles and/or services related to manufacturing an IC device 1360. The entities in system 1300 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1320, mask house 1330, and IC fab 1350 is owned by a single larger company. In some embodiments, two or more of design house 1320, mask house 1330, and IC fab 1350 coexist in a common facility and use common resources.

Design house (or design team) 1320 generates an IC design layout diagram 1322 (e.g., a layout plan). IC design layout diagram 1322 includes various geometrical patterns designed for an IC device 1360. The geometrical patterns correspond to patterns of metal, oxide, or semiconductor layers that make up the various components of IC device 1360 to be fabricated. The various layers combine to form various IC features. For example, a portion of IC design layout diagram 1322 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1320 implements a proper design procedure to form IC design layout diagram 1322. The design procedure includes one or more of logic design, physical design or place and route. IC design layout diagram 1322 is presented in one or more data files having information of the geometrical patterns. For example, IC design layout diagram 1322 can be expressed in a GDSII file format or DFII file format.

Mask house 1330 includes data preparation 1332 and mask fabrication 1344. Mask house 1330 uses IC design layout diagram 1322 to manufacture one or more masks 1345 to be used for fabricating the various layers of IC device 1360 according to IC design layout diagram 1322. Mask house 1330 performs mask data preparation 1332, where IC design layout diagram 1322 is translated into a representative data file (RDF). Mask data preparation 1332 provides the RDF to mask fabrication 1344. Mask fabrication 1344 includes a mask writer. A mask writer converts the RDF to an image on a substrate, such as a mask (reticle) 1345 or a semiconductor wafer 1353. The design layout diagram 1322 is manipulated by mask data preparation 1332 to comply with particular characteristics of the mask writer and/or requirements of IC fab 1350. In FIG. 13, mask data preparation 1332 and mask fabrication 1344 are illustrated as separate elements. In some embodiments, mask data preparation 1332 and mask fabrication 1344 can be collectively referred to as mask data preparation.

In some embodiments, mask data preparation 1332 includes optical proximity correction (OPC) which uses lithography enhancement techniques to compensate for image errors, such as those that can arise from diffraction, interference, other process effects and the like. OPC adjusts IC design layout diagram 1322. In some embodiments, mask data preparation 1332 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1332 includes a mask rule checker (MRC) that checks the IC design layout diagram 1322 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1322 to compensate for photolithographic implementation effects during mask fabrication 1344, which may undo part of the modifications performed by OPC in order to meet mask creation rules.

In some embodiments, mask data preparation 1332 includes lithography process checking (LPC) that simulates processing that will be implemented by IC fab 1350 to fabricate IC device 1360. LPC simulates this processing based on IC design layout diagram 1322 to create a simulated manufactured device, such as IC device 1360. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1322.

It should be understood that the above description of mask data preparation 1332 has been simplified for the purposes of clarity. In some embodiments, data preparation 1332 includes additional features such as a logic operation (LOP) to modify the IC design layout diagram 1322 according to manufacturing rules. Additionally, the processes applied to IC design layout diagram 1322 during data preparation 1332 may be executed in a variety of different orders.

After mask data preparation 1332 and during mask fabrication 1344, a mask 1345 or a group of masks 1345 are fabricated based on the modified IC design layout diagram 1322. In some embodiments, mask fabrication 1344 includes performing one or more lithographic exposures based on IC design layout diagram 1322. In some embodiments, an electron-beam (e-beam) or a mechanism of multiple e-beams is used to form a pattern on a mask (photomask or reticle) 1345 based on the modified IC design layout diagram 1322. Mask 1345 can be formed in various technologies. In some embodiments, mask 1345 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1345 includes a transparent substrate (e.g., fused quartz) and an opaque material (e.g., chromium) coated in the opaque regions of the binary mask. In another example, mask 1345 is formed using a phase shift technology. In a phase shift mask (PSM) version of mask 1345, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1344 is used in a variety of processes. For example, such a mask(s) is used in an ion implantation process to form various doped regions in semiconductor wafer 1353, in an etching process to form various etching regions in semiconductor wafer 1353, and/or in other suitable processes.

IC fab 1350 is an IC fabrication business that includes one or more manufacturing facilities for the fabrication of a variety of different IC products. In some embodiments, IC fab 1350 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1350 includes fabrication tools 1352 configured to execute various manufacturing operations on semiconductor wafer 1353 such that IC device 1360 is fabricated in accordance with the mask(s), e.g., mask 1345. In various embodiments, fabrication tools 1352 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1350 uses mask(s) 1345 fabricated by mask house 1330 to fabricate IC device 1360. Thus, IC fab 1350 at least indirectly uses IC design layout diagram 1322 to fabricate IC device 1360. In some embodiments, semiconductor wafer 1353 is fabricated by IC fab 1350 using mask(s) 1345 to form IC device 1360. In some embodiments, the IC fabrication includes performing one or more lithographic exposures based at least indirectly on IC design layout diagram 1322. Semiconductor wafer 1353 includes a silicon substrate or other proper substrate having material layers formed thereon. Semiconductor wafer 1353 further includes one or more of various doped regions, dielectric features, multilevel interconnects, and the like (formed at subsequent manufacturing steps).

In some aspects, a semiconductor device includes a memory cell array, a first conductive structure configured to carry a first control signal for an operation of a set of memory cells of the memory cell array, and a second conductive structure electrically coupled to the first conductive structure and configured to carry the first control signal for the operation of the set of memory cells of the memory cell array. Memory cells of the set of memory cells are arranged along a first horizontal direction. The first conductive structure and the second conductive structure extend along the first horizontal direction. The first conductive structure and the second conductive structure are spaced apart in a second horizontal direction, in a vertical direction, or both.

In some aspects, a method of manufacturing a semiconductor device includes forming a memory cell array over a substrate, disposing a first conductive structure over the substrate, and disposing a second conductive structure over the substrate. The first conductive structure is configured to carry a first control signal for an operation of a set of memory cells of the memory cell array. The second conductive structure is electrically coupled to the first conductive structure and configured to carry the first control signal for the operation of the set of memory cells of the memory cell array. Memory cells of the set of memory cells are arranged along a first horizontal direction. The first conductive structure and the second conductive structure extend along the first horizontal direction. The first conductive structure and the second conductive structure are spaced apart in a second horizontal direction, in a vertical direction, or both.

In some aspects, a semiconductor device includes a memory cell array over a substrate, and a first plurality of conductive structures included in a first plurality of metallization layers over the memory cell array. The first plurality of conductive structures being electrically coupled to one another and configured to carry a first control signal for an operation of a first set of memory cells of the memory cell array. Memory cells of the first set of memory cells are arranged along a first horizontal direction. Each one of the first plurality of conductive structures extends along the first horizontal direction and overlapping the first set of memory cells.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

1. A semiconductor device, comprising:
a memory cell array;
a first conductive structure configured to carry a first control signal for an operation of a set of memory cells of the memory cell array; and
a second conductive structure electrically coupled to the first conductive structure and configured to carry the first control signal for the operation of the set of memory cells of the memory cell array,
wherein
memory cells of the set of memory cells are arranged along a first horizontal direction,
the first conductive structure and the second conductive structure extend along the first horizontal direction, and
the first conductive structure and the second conductive structure are spaced apart in a second horizontal direction, in a vertical direction, or both.

2. The semiconductor device of claim 1, further comprising:
a third conductive structure extending along the second horizontal direction; and
a plurality of via structures connecting the third conductive structure and the first conductive structure and the second conductive structure,
wherein
the first conductive structure and the second conductive structure are included in a same metallization layer.

3. The semiconductor device of claim 2, wherein
the third conductive structure corresponds to a drain/source terminal structure over a substrate of the semiconductor device.

4. The semiconductor device of claim 1, wherein
the first conductive structure corresponds to a gate structure over a substrate of the semiconductor device, and
the second conductive structure is included in a metallization layer over the first conductive structure and over the substrate of the semiconductor device.

5. The semiconductor device of claim 4, wherein
the second conductive structure includes
a first portion having a first line width along the second horizontal direction that is equal to or greater than a default line width associated with the metallization layer, and
a second portion having a second line width along the second horizontal direction and greater than the first line width.

6. The semiconductor device of claim 4, wherein
each memory cell of the memory cell array has a cell width along the second horizontal direction,
the second conductive structure has a line width along the second horizontal direction,
in response to an adjacent conductive structure configured to carry a second control signal of a same type as the first control signal and the adjacent conductive structure and the second conductive structure being at a same metallization layer, the line width ranges from a default line width associated with the metallization layer to a difference between the cell width and a minimal line space associated with the metallization layer, and
in response to the adjacent conductive structure and the second conductive structure being at different metallization layers, the line width is equal to or greater than the cell width.

7. The semiconductor device of claim 1, wherein
the first conductive structure and the second conductive structure are at different metallization layers over a substrate of the semiconductor device.

8. The semiconductor device of claim 1, further comprising:
one or more other conductive structures electrically coupled to the first conductive structure, and extending along the first horizontal direction,
wherein
the first conductive structure, the second conductive structure, and the one or more other conductive structures are at different metallization layers over a substrate of the semiconductor device.

9. The semiconductor device of claim 1, wherein
the first conductive structure and the second conductive structure correspond to a source line of the memory cell array, a bit line of the memory cell array, or a word line of the memory cell array.

10. The semiconductor device of claim 1, wherein
the memory cell array includes memory cells that are
volatile memory cells including dynamic random access memory (DRAM) cells or static random access memory (SRAM) cells, or
non-volatile memory cells including floating-gate memory cells, ferroelectric random access memory (FRAM) cells, magnetic random access memory (MRAM) cells, phase-change memory (PCM) cells, or resistive random access memory (RRAM) cells.

11. The semiconductor device of claim 1, further comprising:
a third conductive structure configured to carry a second control signal for an operation of a second set of memory cells of the memory cell array; and
a fourth conductive structure electrically coupled to the third conductive structure and configured to carry the second control signal for the operation of the second set of memory cells of the memory cell array,
wherein
memory cells of the second set of memory cells are arranged along the second horizontal direction,
the third conductive structure and fourth conductive structure extend along the second horizontal direction, and
the third conductive structure and the fourth conductive structure are spaced apart in the first horizontal direction, in the vertical direction, or both.

12. The semiconductor device of claim 11, wherein
the first conductive structure is included in a first metallization layer over the memory cell array,
the second conductive structure is included in a second metallization layer over the first metallization layer,
the third conductive structure is included in a third metallization layer over the first conductive structure,
the fourth conductive structure is included in a fourth metallization layer over the third conductive structure, and
the third conductive structure is over or under the second conductive structure.

13. A method of manufacturing a semiconductor device, comprising:
forming a memory cell array over a substrate;
disposing a first conductive structure over the substrate, the first conductive structure being configured to carry a first control signal for an operation of a set of memory cells of the memory cell array; and
disposing a second conductive structure over the substrate, the second conductive structure being electrically coupled to the first conductive structure and configured to carry the first control signal for the operation of the set of memory cells of the memory cell array,
wherein
memory cells of the set of memory cells are arranged along a first horizontal direction,
the first conductive structure and the second conductive structure extend along the first horizontal direction, and
the first conductive structure and the second conductive structure are spaced apart in a second horizontal direction, in a vertical direction, or both.

14. The method of claim 13, further comprising:
forming a metallization layer including the first conductive structure and the second conductive structure;
disposing a third conductive structure over the substrate and extending along the second horizontal direction; and
disposing a plurality of via structures connecting the third conductive structure and the first conductive structure and the second conductive structure.

15. The method of claim 13, wherein
the disposing the second conductive structure comprises:
forming a metallization layer over the first conductive structure and including the second conductive structure;
forming a first portion of the second conductive structure having a first line width along the second horizontal direction that is equal to or greater than a default line width associated with the metallization layer, and
forming a second portion of the second conductive structure having a second line width along the second horizontal direction and being greater than the first line width.

16. The method of claim 13, wherein
each memory cell of the memory cell array has a cell width along the second horizontal direction,
in response to an adjacent conductive structure configured to carry a second control signal of a same type as the first control signal and the adjacent conductive structure and the second conductive structure being at a same metallization layer, the disposing the second conductive structure comprises forming the second conductive structure having a line width along the second horizontal direction, and the line width ranging from a default line width associated with the metallization layer to a difference between the cell width and a minimal line space associated with the metallization layer, and
in response to the adjacent conductive structure and the second conductive structure being at different metallization layers, the disposing the second conductive structure comprises forming the second conductive structure having the line width equal to or greater than the cell width.

17. The method of claim 13, further comprising:
forming two different metallization layers including the first conductive structure and the second conductive structure;
forming one or more other metallization layers including one or more other corresponding conductive structures,
wherein the one or more other conductive structures are electrically coupled to the first conductive structure, and extend along the first horizontal direction.

18. A semiconductor device, comprising:
a memory cell array over a substrate; and
a first plurality of conductive structures included in a first plurality of metallization layers over the memory cell array, the first plurality of conductive structures being electrically coupled to one another and configured to carry a first control signal for an operation of a first set of memory cells of the memory cell array,
wherein
memory cells of the first set of memory cells are arranged along a first horizontal direction, and
each one of the first plurality of conductive structures extends along the first horizontal direction and overlapping the first set of memory cells.

19. The semiconductor device of claim 18, further comprising:
a second plurality of conductive structures included in a second plurality of metallization layers over the memory cell array, the second plurality of conductive structures being electrically coupled to one another and configured to carry a second control signal for an operation of a second set of memory cells of the memory cell array,
wherein
memory cells of the second set of memory cells are arranged along a second horizontal direction, and
each one of the second plurality of conductive structures extends along the second horizontal direction.

20. The semiconductor device of claim 19, further comprising:
a third plurality of conductive structures included in a third plurality of metallization layers over the memory cell array, the third plurality of conductive structures being electrically coupled to one another and configured to carry a third control signal for the operation of the first set of memory cells of the memory cell array,
wherein
each one of the third plurality of conductive structures extends along the first horizontal direction.
